(19) United States
(12) Patent Application Publication
(10) Pub. No.: US 2025/0271766 A1
(43) Pub. Date: Aug. 28, 2025

(54) METAL CHELATORS FOR DEVELOPMENT OF METAL-CONTAINING PHOTORESIST

(71) Applicant: Lam Research Corporation, Fremont, CA (US)

(72) Inventors: Eric Calvin HANSEN, San Jose, CA (US); Timothy William WEIDMAN, Sunnyvale, CA (US); Chenghao WU, San Jose, CA (US); Kevin Li GU, Mountain View, CA (US); Dries DICTUS, Kessel-Lo (BE)

(21) Appl. No.: 19/202,425

(22) Filed: May 8, 2025

Related U.S. Application Data
(63) Continuation of application No. 18/005,571, filed on Jan. 13, 2023.
(60) Provisional application No. 62/705,855, filed on Jul. 17, 2020.

(51) Int. Cl. G03F 7/32; G03F 7/004; G03F 7/16; G03F 7/20; G03F 7/38

(52) U.S. Cl. CPC G03F 7/325; G03F 7/0043; G03F 7/162; G03F 7/2004; G03F 7/38

(57) ABSTRACT

The present disclosure relates to the use of a metal chelator to treat an exposed photoresist film. In particular embodiments, the metal chelator is employed to remove an interfacial area that is disposed between exposed and unexposed areas or disposed within an exposed area, thereby enhancing patterning quality.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### FIELD

The present disclosure relates to the use of a metal chelator to treat exposed photoresist films. In particular embodiments, the metal chelator is employed to remove an interfacial area that is disposed between exposed and unexposed areas or disposed within an exposed area, thereby enhancing patterning quality.

### BACKGROUND

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

Patterning of thin films in semiconductor processing is often an important step in the fabrication of semiconductors. Patterning involves lithography. In photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with other photolithography methods. EUV light sources at approximately 10-20 nm, or 11-14 nm wavelength, for example 13.5 nm wavelength, can be used for leading-edge lithography tools, also referred to as scanners. EUV radiation is strongly absorbed in a wide range of solid and fluid materials including quartz and water vapor, and so operates in a vacuum.

### SUMMARY

The present disclosure relates to the use of one or more metal chelator(s) during development (e.g., wet development) of a metal-based photoresist (PR). During lithographic exposure of organometallic-based PRs, an interfacial area between lithographically exposed and unexposed areas can exist. As discussed herein, this interfacial area can be characterized as an area that transitions sharply from the most exposed area to a completely unexposed area. Thus, in this interfacial area, the composition of the PR can include various partial reaction products that are different from products present in the most exposed area and those present in the completely unexposed area. Such reaction products can lead to roughness after wet development processes. In addition, this interfacial area can span a short distance, e.g., a nanometer or two; and the general composition within this interfacial area is approximately that which is required at dose threshold for wet development.

At this interfacial area, weakly bound metal species can be present. As described herein, the present disclosure provides for removal of such metal species with metal chelator(s), which can, e.g., provide improved resultant patterning quality, especially regarding line-width-roughness (LWR) and/or line-edge-roughness (LER).

Accordingly, in a first aspect, the present disclosure features a method including: providing a radiation patterned film (e.g., an exposed film) having an interfacial area; and developing the radiation patterned film in the presence of a metal chelator (e.g., or two or more different metal chelators), wherein the metal chelator is configured to bind to one or more radiation exposed metal centers of the interfacial area. In some embodiments, the radiation exposed metal center is a weakly bound metal species (e.g., characterized by one, two, or three metal-oxygen bonds). The interfacial area can be disposed between a radiation exposed area and a radiation unexposed area or disposed within a radiation exposed area (e.g., between a highly exposed and less exposed areas). In some embodiments, the interfacial area includes an interface or a transition area disposed between the highly exposed and unexposed areas or between the highly exposed and less exposed areas.

In particular embodiments, the exposed film or the radiation patterned film includes an Extreme Ultraviolet (EUV)-sensitive film. In other embodiments, the exposed film or the radiation patterned film is characterized by an exposure to EUV radiation, thereby having EUV exposed areas, EUV unexposed area, and an interfacial area disposed between the EUV exposed area and the EUV unexposed area. In yet other embodiments, the interfacial area includes an area that is less exposed to EUV radiation (e.g., as compared to an area that is highly exposed to EUV radiation). In particular embodiment, the interfacial area is within the EUV exposed area.

In some embodiments, as used herein, a “radiation exposed area” can include an area having variable exposure to radiation. For instance, a dosage curve (as a function of distance) within the radiation exposed area can be non-linear, such that certain regions within a radiation exposed area can be exposed to a higher radiation dosage and other regions within the radiation exposed area can be exposed to a lower radiation dosage. As the extent of radiation dosage can affect the extent of reaction within the PR, a variety of reaction products can exist within the radiation exposed area. Thus, in some embodiments, the radiation exposed area can be considered to include an interfacial area that transitions sharply from the most exposed area to a less exposed area.

In some embodiments, said developing further includes removing the interfacial area. Such removing can provide improved LWR and/or LER (e.g., characterized by reduced high frequency noise as determined by power spectral density measurements to differentiate between different sources of line roughness, such as high, medium, and low frequency sources), as compared to developing without the metal chelator. For instance, use of a chelator could reduce high to medium frequency roughness by smoothing out localized perturbations to the line shape of the power spectral density curve. In particular embodiments, said developing includes providing the metal chelator with a solvent or a solvent mixture (e.g., any described herein).

In other embodiments, said developing further includes employing a solvent or a solvent mixture that preferentially removes the radiation exposed area, as compared to the radiation unexposed area. In some embodiments, the metal chelator is soluble in the solvent or the solvent mixture. In particular embodiments, the metal chelator preferentially binds to the radiation exposed metal center of the interfacial area, as compared to a metal center present in the radiation unexposed area.

In some embodiments, the metal chelator includes a dicarbonyl (e.g., a 1,3-diketone), a diol, a carboxylic acid (e.g., R^{A1}—CO₂H, in which R^{A1} is H, optionally substituted alkyl, optionally substituted hydroxyalkyl, optionally substituted hydroxyaryl, optionally substituted carboxyalkyl, optionally substituted carboxyaryl, or optionally substituted aryl), a diacid, a triacid, a hydroxycarboxylic acid, a hydroxamic acid (e.g., R^{A1}—C(O)NR^{A2}OH, in which each of R^{A1} and R^{A2} is, independently, H, optionally substituted alkyl, or optionally substituted aryl), a hydroxylactone, a hydroxyketone (e.g., a hydroxypyridinone, a hydroxypyrimidone, or a hydroxypyrone), or a salt thereof. In other embodiments, the metal chelator includes formic acid, citric acid, acetylacetone, salicylic acid, catechol, or ascorbic acid.

In other embodiments, the metal chelator includes a hydroxyketone having a structure of formula (I), (II), or (III):

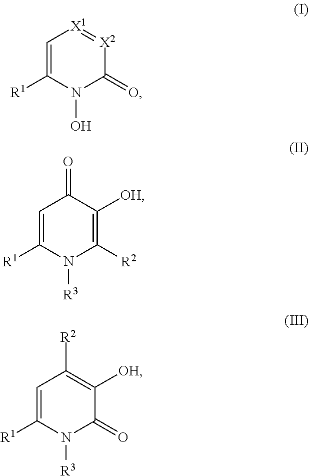

or a salt thereof, wherein:
each of X¹ and X² is, independently, —CR¹═ or —N═;
each R¹ and R² is, independently, H, optionally substituted alkyl, optionally substituted hydroxyalkyl, optionally substituted carboxyalkyl, —C(O)NR^{N1}R^{N2}, or —C(O)OR^{O1}, wherein each of R^{N1}, R^{N2}, and R^{O1} is, independently, H, or optionally substituted alkyl, in which optionally R^{N1} and R^{N2}, when taken together, forms an optionally substituted heterocyclyl; and
R³ is, independently, H, optionally substituted alkyl, or optionally substituted aryl.

In some embodiments, the metal chelator includes a plurality of moieties disposed on a backbone, wherein the plurality of moieties is selected from hydroxyl, carboxyl, amido, amino, and oxo. Non-limiting moieties include one or more of a monovalent or multivalent form of a dicarbonyl, a diol, a carboxylic acid, a diacid, a triacid, a hydroxycarboxylic acid, a hydroxamic acid, a hydroxylactone, a hydroxyketone, or a salt thereof.

In some embodiments, the radiation exposed metal center includes a transition metal. Non-limiting metal centers include, e.g., tin (Sn), tellurium (Te), bismuth (Bi), antimony (Sb), tantalum (Ta), cesium (Cs), indium (In), molybdenum (Mo), or hafnium (Hf).

The exposed film or the radiation patterned film can be formed from any useful metal precursor (e.g., any described herein). In particular embodiments, the metal precursor includes a structure having formula (IV):

MₐR_{b} (IV),
wherein: M is a metal (e.g., any described herein, such as Sn, Te, Bi, Sb, Ta, Cs, In, Mo, or Hf); each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand; a≥1 (e.g., a is 1, 2, or 3); and b≥1 (e.g., b is 1, 2, 3, 4, 5, 6, 7, 8, 9, 10, 11, or 12).

In a second aspect, the present disclosure encompasses a method (e.g., of employing a resist) including: depositing a metal precursor on a surface of a substrate to provide a patterning radiation-sensitive film as a resist film; patterning the resist film by a patterning radiation exposure; and developing the exposed film in the presence of a metal chelator and a solvent. In some embodiments, said depositing includes use of a counter-reactant (e.g., an oxygen-containing counter-reactant, such as any described herein).

In other embodiments, said patterning provides an exposed film having one or more radiation exposed areas, one or more radiation unexposed areas, and an interfacial area disposed between at least one of the radiation exposed areas and at least one of the radiation unexposed areas. In some embodiments, the radiation exposure (e.g., the patterning radiation exposure) includes an EUV exposure having a wavelength in the range of about 10 nm to about 20 nm in a vacuum ambient.

In further embodiments, said developing removes the interfacial area and either the radiation exposed or radiation unexposed areas to provide a pattern within the resist. In some embodiments, the pattern includes a reduced LER and/or LWR, as compared to a pattern developed without the metal chelator.

In some embodiments, the metal chelator is configured to preferentially remove the interfacial area (e.g., as compared to the radiation exposed area and/or the radiation unexposed area). In further embodiments, the solvent is configured to preferentially remove either of the radiation exposed areas or the radiation unexposed areas (e.g., as compared to the interfacial area).

In some embodiments, the method further includes (e.g., after said development): removing the metal chelator and/or metal-chelate complex from the film.

In a third aspect, the present disclosure encompasses an apparatus (e.g., for forming a resist film) including: a deposition module; a patterning module; a development module; and a controller including one or more memory devices, one or more processors, and system control software coded with instructions including machine-readable instructions.

In some embodiments, the deposition module includes a chamber for depositing a patterning radiation-sensitive film (e.g., an EUV-sensitive film). In other embodiments, the patterning module includes a photolithography tool with a source of sub-300 nm wavelength radiation (e.g., in which the source can be a source of sub-30 nm wavelength radiation). In yet other embodiments, the development module includes a chamber for developing the resist film.

In particular embodiments, the controller instructions include machine-readable instructions for (e.g., in the deposition module) causing deposition of a metal precursor on a top surface of a semiconductor substrate to form the patterning radiation-sensitive film as a resist film. In other embodiments, the controller instructions include machine-readable instructions for (e.g., in the patterning module) causing patterning of the resist film with sub-300 nm resolution (e.g., or with sub-30 nm resolution) directly by patterning radiation exposure, thereby forming an interfacial area disposed between at least one radiation exposed area and at least one radiation unexposed area. In particular embodiments, the interfacial area is an area that is less exposed to EUV radiation (as compared to another area that is more highly exposed to EUV radiation); or is a transition area that is disposed between at least one EUV exposed area and at least one EUV unexposed area; or is a transition area that is disposed between at least one highly EUV exposed area and at least one less EUV exposed area.

In some embodiments, the controller instructions include machine-readable instructions for (e.g., in the development module) causing development of the exposed film in the presence of a metal chelator and a solvent. In particular embodiments, said development removes the interfacial area and at least one of the radiation exposed areas or the radiation unexposed areas to provide a pattern within the resist film. In other embodiments, the machine-readable instructions include instructions for causing removal of the interfacial area. In yet other embodiments, the machine-readable instructions include instructions for causing removal of the EUV exposed areas or the EUV unexposed areas.

In any embodiment herein, the metal chelator includes a dicarbonyl (e.g., a 1,3-diketone, such as acetylacetone), a hydroxyalkyl, a hydroxyaryl, a diol (e.g., glycol, catechol, etc.), a carboxylic acid (e.g., R^{A1}—CO₂H, in which R^{A1} is H, optionally substituted alkyl, optionally substituted hydroxyalkyl, optionally substituted carboxyalkyl, or optionally substituted aryl; including formic acid or citric acid), a diacid, a triacid, a hydroxycarboxylic acid (e.g., a phenolic acid, such as salicylic acid), a hydroxamic acid (e.g., R^{A1}. C(O)NR^{A2}OH, in which each of R^{A1} and R^{A2} is, independently, H, optionally substituted alkyl, or optionally substituted aryl), a hydroxylactone (e.g., ascorbic acid), a hydroxyketone (e.g., a hydroxypyridinone, a hydroxypyrimidone, or a hydroxypyrone, such as those having a structure of formula (I), (II), or (III), as described herein), or a salt thereof. In other embodiments, the metal chelator includes a plurality of moieties disposed on a backbone, wherein the plurality of moieties is selected from hydroxyl, carboxyl, amido, amino, and oxo. Non-limiting moieties include one or more of a monovalent or multivalent form of a dicarbonyl, a diol, a carboxylic acid, a diacid, a triacid, a hydroxycarboxylic acid, a hydroxamic acid, a hydroxylactone, a hydroxyketone, or a salt thereof.

In any embodiment herein, the exposed film or the patterning radiation-sensitive film includes a metal oxide film or an organometal oxide film or an organometallic material.

In any embodiment herein, the exposed film or the patterning radiation-sensitive film includes an EUV-sensitive film.

In any embodiment herein, the exposed film or the patterning radiation-sensitive film includes a metal having a high patterning radiation-absorption cross-section. In particular embodiments, the metal includes a high EUV absorption cross-section. In other embodiments, the metal layer includes tin (Sn), tellurium (Te), bismuth (Bi), antimony (Sb), tantalum (Ta), cesium (Cs), indium (In), molybdenum (Mo), or hafnium (Hf), as well as combinations thereof.

In any embodiment herein, the metal precursor includes a structure having formula (IV), (V), (Va), (VI), (VII), (VIII), (IX), (X), and (XI), as described herein.

In any embodiment herein, depositing includes providing or depositing the metal precursor in vapor form. In other embodiments, depositing includes providing a counter-reactant in vapor form. In particular embodiments, depositing includes chemical vapor deposition (CVD), atomic layer deposition (ALD), or molecular layer deposition (MLD), and plasma-enhanced forms thereof.

In any embodiment herein, depositing of the metal layer further includes providing a counter-reactant. Non-limiting counter-reactants include an oxygen-containing counter-reactant, including O₂, O₃, water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof. Additional details follow.

### Definitions

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkenylene” is meant a multivalent (e.g., bivalent) form of an alkenyl group, as defined herein. The alkenylene group can be substituted or unsubstituted. For example, the alkenylene group can be substituted with one or more substitution groups, as described herein for alkyl.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O) H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)-Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amido” is meant —C(O)NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group, as defined herein.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “carbonyl” is meant a —C(O)-group, which can also be represented as >C═O.

By “carboxyl” is meant a —CO₂H group.

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “carboxylic acid” is meant any moiety or compound including one or more carboxyl groups. Exemplary, non-limiting carboxylic acids include a carboxyalkyl or a carboxyaryl. As used herein, “diacid” refers to a carboxylic acid having two carboxyl groups, and “triacid” refers to a carboxylic acid having three carboxyl groups.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.] heptyl, and the like. The cycloalkyl group can also be substituted or unsubstituted. For example, the cycloalkyl group can be substituted with one or more groups including those described herein for alkyl.

By “dicarbonyl” is meant any moiety or compound including two carbonyl groups, as defined herein. Non-limiting dicarbonyl moieties include 1,2-dicarbonyl (e.g., R^{C1}—C(O)—C(O)R^{C2}, in which each of R^{C1} and R^{C2} is, independently, optionally substituted alkyl, halo, optionally substituted alkoxy, hydroxyl, or a leaving group); 1,3-dicarbonyl or 1,3-diketone (e.g., R^{C1}—C(O)—C(R^{1a}R^{2a})—C(O)R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O)R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein).

By “diol” is meant a hydroxyalkyl or a hydroxyaryl, as defined herein, including two hydroxyl groups.

By “halo” is meant F, Cl, Br, or I.

By “haloalkyl” is meant an alkyl group, as defined herein, substituted with one or more halo.

By “heteroalkenylene” is meant a bivalent form of an alkenylene group, as defined herein, containing one, two, three, or four non-carbon heteroatoms (e.g., independently selected from the group consisting of nitrogen, oxygen, phosphorous, sulfur, selenium, or halo). The heteroalkenylene group can be substituted or unsubstituted. For example, the heteroalkenylene group can be substituted with one or more substitution groups, as described herein for alkyl. Non-limiting heteroalkenylene groups include, e.g., —NR^{N1}-Ak-, -Ak-NR^{N1}. —O-Ak-, or -Ak-O—, in which Ak is an optionally substituted alkenylene, as defined herein.

By “heteroalkylene” is meant a bivalent form of an alkylene group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl. Non-limiting heteroalkylene groups include, e.g., —NR^{N1}-Ak-, -Ak-NR^{N1}—, —O-Ak-, or -Ak-O—, in which Ak is an optionally substituted alkylene, as defined herein.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydroxamic acid” is mean a carboxylic acid, as defined herein, having a hydroxyamino group replace the hydroxyl group. Non-limiting hydroxamic acids include R^{A1}—C(O)NR^{A2}OH, in which each of R^{A1} and R^{A2} is, independently, H, optionally substituted alkyl, or optionally substituted aryl.

By “hydroxyl” is meant-OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “hydroxycarboxylic acid” is meant any moiety or compound having at least one hydroxyl group and at least one carboxyl group.

By “hydroxyketone” is meant any moiety or compound having a carbonyl group and a hydroxyl group as substitutions. In particular instances, the carbonyl group can form a ketone or an amide. Non-limiting hydroxyketones include R^{A1}—C(O)—R^{A2}, in which each of R^{A1} and R^{A2} is an optionally substituted alkylene, optionally substituted alkenylene, an optionally substituted heteroalkylene, or an optionally substituted heteroalkenylene, at least one of R^{A1} and R^{A2} includes a hydroxyl substitution, and in which R^{A1} and R^{A2}, taken together, form a cyclic group (e.g., a heterocyclyl, as defined herein).

By “hydroxylactone” is meant a cyclic ester having one or more hydroxyl groups. Non-limiting hydroxylactones include R^{A1}—C(O)—OR^{A2}, in which each of R^{A1} and R^{A2} is an optionally substituted alkylene or optionally substituted alkenylene, at least one of R^{A1} and R^{A2} includes a hydroxyl substitution, and in which R^{A1} and R^{A2}, taken together, form a cyclic group (e.g., a heterocyclyl, as defined herein).

By “oxo” is meant an ═O group.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### BRIEF DESCRIPTION OF THE DRAWINGS

FIG. 1 presents schematic diagrams of a non-limiting method for patterning and developing a film.

FIG. 2A-2B presents schematic diagrams of a non-limiting method for patterning and developing a film in the presence of a chelator.

FIG. 3A-3B presents schematic illustrations and diagrams of non-limiting methods that employ a metal precursor during deposition and a chelator during development. Provided are (A) a first method 300 to provide either a positive tone resist (path i) or a negative tone resist (path ii); and (B) a block diagram of an illustrative method 350.

FIG. 4 presents a schematic illustration of an embodiment of a multi-station processing tool 400.

FIG. 5 presents a schematic illustration of an embodiment of an inductively coupled plasma apparatus 500.

FIG. 6 presents a schematic illustration of an embodiment of a semiconductor process cluster tool architecture 600.

### DETAILED DESCRIPTION

This disclosure relates generally to the field of semiconductor processing. In particular, the disclosure is directed to the use of one or more metal chelators during development. For instance, metal chelators can strongly bind metal ions and selectively remove weakly-bound metals, which likely exist at the rough interface between exposed and unexposed PR areas. Such metal chelators thereby provide a tuning knob to manipulate LER/LWR by manipulating the chelator concentration and/or the chemical identity of the chelator. Without wishing to be limited by mechanism, metal chelators bind metal ions more or less strongly depending on the thermodynamic benefit arising from the formation of chemical bonds, while binding the metals at a rate that depends on the amount of steric hindrance and the physical size of the chelator molecule. As a result, careful choice of the concentration and chemical identity of a chelator can provide a tuning knob to directly manipulate the roughness at the interface of exposed and unexposed areas.

Without a metal chelator, solvent optimization for wet development balances LER with optimization of solubility differences between exposed/unexposed areas. However, use of a soluble metal chelator in the wet developer can directly address the roughness at this interface, while allowing for a solvent optimized for contrast of just the exposed and unexposed areas. The orthogonality between solvent choice and the improvement at the interface from metal chelators allows for optimization of developer contrast between exposed/unexposed areas, while also optimizing LER due to roughness at the interface between exposed/unexposed areas that may be difficult to control without a metal chelator.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria Corp. (Corvallis, OR), and described, for example, in U.S. Pat. Pub. Nos. US 2017/0102612, US 2016/0216606, and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Appl. No. PCT/US19/31618, published as International Pub. No. WO 2019/217749, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

Directly photopatternable EUV or DUV resists may be composed of or contain metals and/or metal oxides mixed within organic components. The metals/metal oxides are highly promising in that they can enhance the EUV or DUV photon absorption, generate secondary electrons, and/or show increased etch selectivity to an underlying film stack and device layers.

Generally, resists can be employed as a positive tone resist or a negative tone resist by controlling the chemistry of the resist and/or the solubility or reactivity of the developer. It would be beneficial to have a EUV or DUV resist that can serve as either a negative tone resist or a positive tone resist, and the present disclosure encompasses use and development of films as either a negative or positive tone resist.

### Methods Employing Metal Chelator(s)

The present disclosure generally includes any useful method that employs a metal chelator, as described herein. Such methods can include any useful lithography processes, deposition processes, radiation exposure processes, development processes, and post-application processes, as described herein.

While the following may describe techniques as relating to EUV processes, such techniques may also be applicable to other next generation lithographic techniques. Various radiation sources may be employed, including EUV (generally about 13.5 nm), DUV (deep-UV, generally in the 248 nm or 193 nm range with excimer laser sources), X-ray (including EUV at the lower energy range of the X-ray range), and e-beam (including a wide energy range).

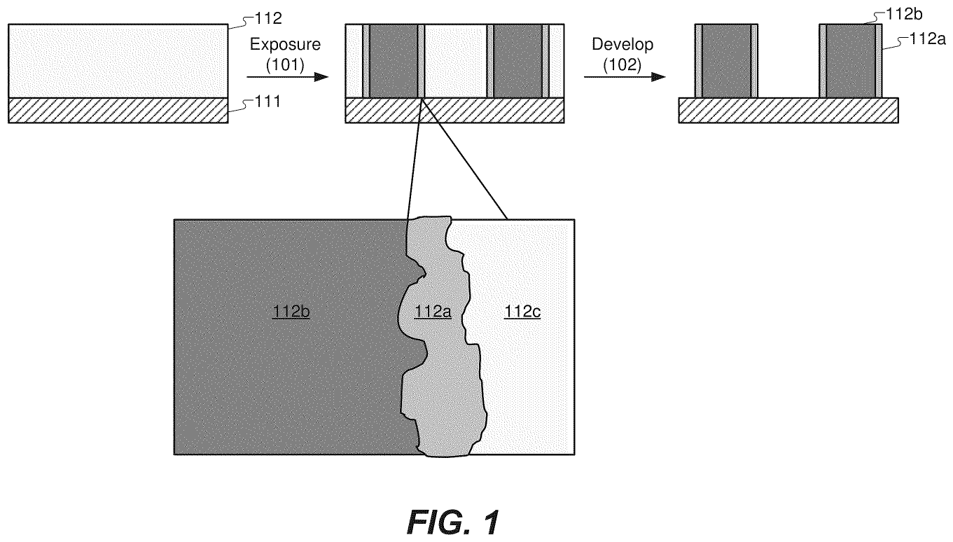

After lithographic exposure to EUV radiation, both EUV exposed and EUV unexposed areas are present within the PR film. As seen in FIG. 1 the EUV-sensitive film 112 can be disposed on a top surface of a substrate 111. The film 112 can be exposed 101 to EUV radiation to provide EUV exposed areas 112b and EUV unexposed areas 112c In a PR film, radiation exposure can be used to generate activated reactive centers, which can in turn promote reactions that either destabilize or stabilize the film to provide a positive or negative tone resist, respectively. For instance, for a negative tone metal-containing resist film, the exposed areas can include EUV-activated reactive centers, which promotes crosslinking and stabilization of the film. Upon development of such a resist, exposed areas are retained, whereas unexposed areas are removed by dissolution of the less stable regions of the film.

Between such exposed and unexposed areas, there are interfacial areas in which an area of the PR transitions sharply from the most exposed area to a completely unexposed area. As can be seen, the exposed film can be characterized by interfacial areas 112a disposed between the exposed/unexposed areas. In such interfacial areas, the film may have been exposed to EUV, thus providing EUV-exposed reactive centers. However, reactions may not proceed to completion, thereby providing regions that is neither fully reacted nor unreacted.

Development of such interfacial areas remains challenging if the development chemistry relies on the completion of such EUV-mediated reactions. As seen in FIG. 1 if the exposed film is developed 102 with such a development chemistry, then the provided pattern includes not only the exposed area 112b but the interfacial area 112a as well. The presence of the interfacial area can reduce fidelity of the pattern within the film and contribute to increased roughness (e.g. increased LER and/or LWR).

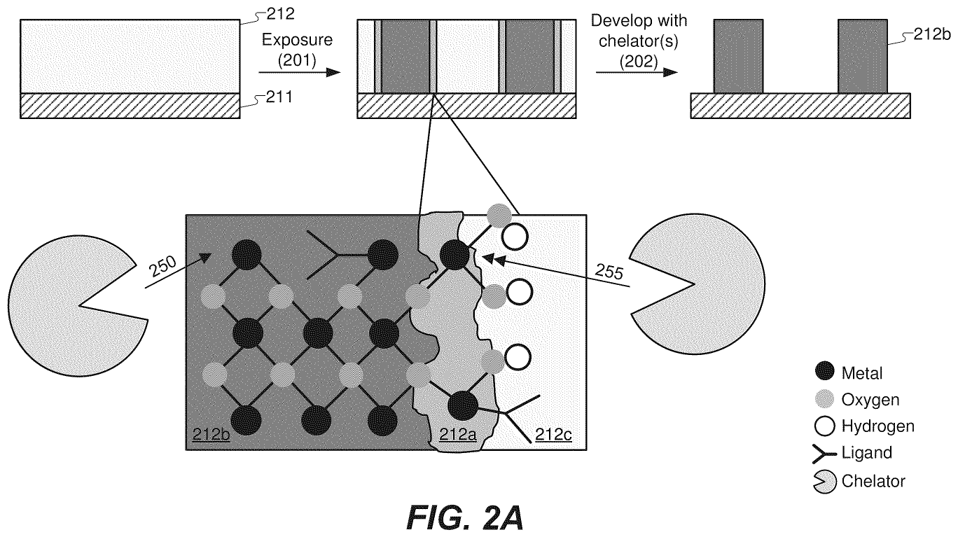

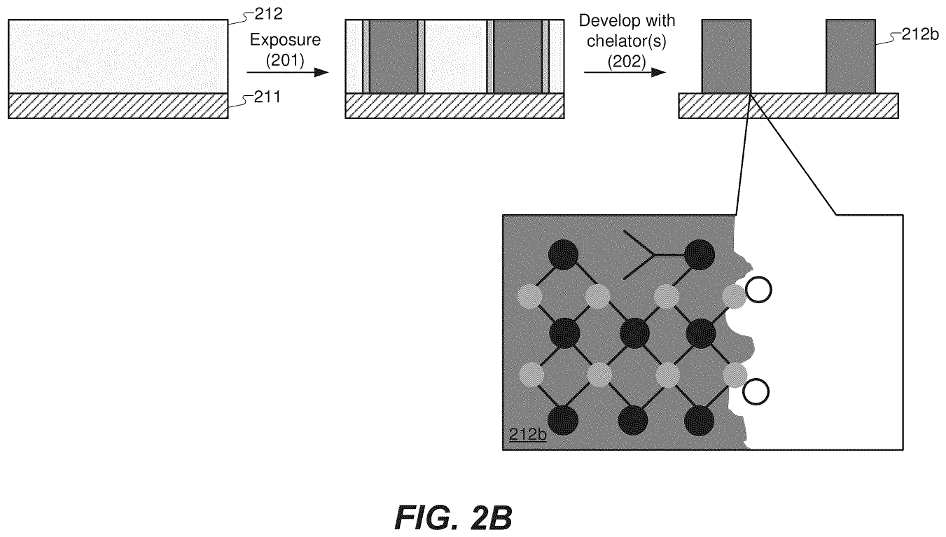

By using a metal chelator that can target unreacted or partially reacted PR regions, the interfacial areas can be removed. As seen in FIG. 2A, a non-limiting method can include exposing 201 a film 212 disposed on a substrate to EUV radiation, thereby providing interfacial regions 212a, EUV exposed regions 212b, and EUV unexposed regions 212c Within EUV exposed regions 212b, the PR is crosslinked to form metal-oxygen (M-O) and metal-oxygen-metal (M-O-M) bonds, as well as to release ligands from the film. As described herein, such EUV exposed regions may include unreacted PR as well. Within EUV unexposed region 212c, the PR has retained the initial chemical structure of the metal precursor, in which EUV-cleavable labile ligands are generally retained. Non-limiting EUV-cleavable labile ligands include any described herein, such as for R in formula (IV) or (V).

Within the interfacial region 212a various chemical species are observed, in which metal centers participate in some degree of crosslinking with the M-O-M phase, some degree of retaining the labile ligand, and some formation of M-OH intermediates. Within this region, the weakly bound metal species can be removed by using metal chelators. In some instances, the chelator can be selected to preferentially bind 255 to the EUV-exposed weakly bound metal species, as compared to binding 250 EUV-exposed crosslinked metal species. After developing 202 the exposed film with such a chelator, the developed film can include a pattern that includes the exposed areas 212b (FIG. 2B).

In particular instances, the metal chelator is a charge-neutral chelator that bind metal ions (e.g., with varying binding strengths), while keeping the resultant metal-chelate complex soluble and stable in the developer solvent (e.g., an organic solvent). As such, the metal chelator can be an organic-soluble metal chelator used in a wet developer to seek out weakly bound metal ions in interfacial areas and bind such metal ions to form a metal-chelate complex. If the metal-chelate complex remains soluble within the developer solvent, then such complexes can be removed from the wafer when the rest of the wet developer is removed. Non-limiting chelators include derivatives of acetylacetone, formic acid, and hydroxypyridinones, as well as others described herein.

The selection of the chelator can depend on any useful chemical and physical property. In one instance, the chelator is selected for its metal binding strength, which can be used to tune how aggressively the interface between exposed and unexposed areas will be impacted by the presence of the chelator. Non-limiting determinations for metal binding strength can include a stability constant (e.g., log K or log β) to be between about 5 to about 50. In another instance, the physical size of the chelator (e.g., between about 0.1 nm to about 10 nm), which can be manipulated by appending a polymeric backbone, can be used to tune what size (e.g., 10 nm critical dimension or greater) or geometry (e.g., flat) features are impacted through the use of the metal chelator.

The presence of a metal chelators during wet development could provide an additional tuning knob to improve LER of developed PR patterns. Using different organic-soluble metal chelators, specific organometallic processes can have LER optimized by choosing an appropriate chelator with binding strength sufficient to remove different types of rough spots in the PR at the interface between exposed and unexposed areas. Such chelator-solvent combinations can be optimized by the chemical type of each compound, as well as particular concentration of chelator within the solvent or solvent mixture.

In addition to promoting removal of metal species, use of such chelators could facilitate removal of volatile compounds generated by or within the PR film. Non-limiting volatile compounds include carbon dioxide, carbon monoxide, alkenes, aromatics, and multi-alkyl tin species that may be present in the film. Non-limiting species include SnRₓL_{y}, in which each R is, independently, optionally substituted alkyl, each L is, independently, dialkylamino (e.g., —NMe₂), hydroxyl, bridging oxide, or another ligand, 4≥x≥1, and 3≥y≥0.

In this way, volatile compounds that may otherwise outgas and contaminate facilities and equipment could be solubilized as a complex within the solvent. Furthermore, chelators can also be used to remove poorly-soluble chemical byproducts that can be generated during EUV exposure and disposed on the surface of lithographically patterned PR.

Removal of the interfacial area, as well as presence of chelated complexes, can be characterized in any useful manner. For instance, dissolution of metal centers by the chelator can be detected by measuring the presence of the metal chelate complex within the developer solution. Non-limiting detection methods include use of nuclear magnetic resonance (NMR) spectroscopy, liquid chromatography-mass spectrometry (LC-MS), high performance liquid chromatography (HPLC), etc.

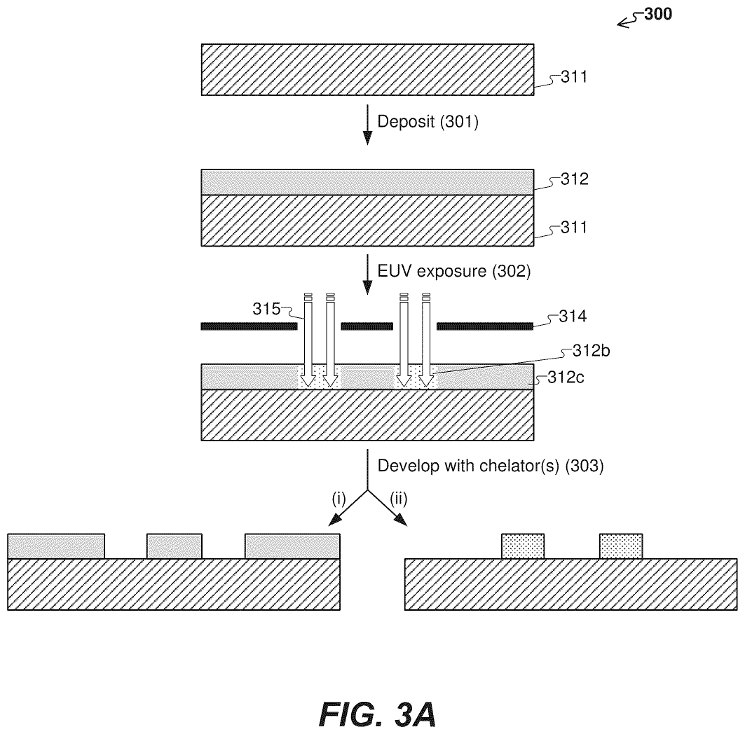

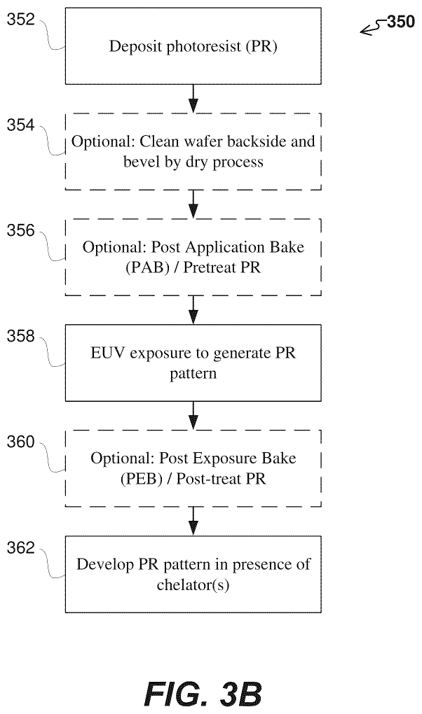

FIG. 3A provides an exemplary method 300, which includes depositing 301 a film 312 on a top surface of a substrate 311. The method can further include steps to treat a deposited EUV-sensitive film. Such steps, while not required for creating the film, can be useful for using the film as a PR. Accordingly, the method 300 further includes patterning the film by an EUV exposure 302 to provide an exposed film having EUV exposed areas 312b and EUV unexposed areas 312c, as well as interfacial areas disposed therebetween. Patterning can include use of a mask 314 having EUV transparent regions and EUV opaque regions, in which EUV beams 315 are transmitted through the EUV transparent region and into the film 312 EUV exposure can include, e.g., an exposure having a wavelength in the range of about 10 nm to about 20 nm in a vacuum ambient (e.g., about 13.5 nm in a vacuum ambient).

Once a pattern is provided, the method 300 can include developing 303 the film in the presence of one or more metal chelator(s), thereby either (i) removing the EUV exposed areas to provide a pattern within a positive tone resist film or (ii) removing the EUV unexposed areas to provide a pattern within a negative tone resist. As described herein, interfacial areas may exist between the EUV exposed/unexposed area. Accordingly, in one embodiment, path (i) in FIG. 3A results in selectively removing the EUV exposed areas 312b and interfacial areas, which can be facilitated by using a metal chelator to bind to weakly bound metal species formed after EUV exposure. Alternatively, path (ii) in FIG. 3A results in maintaining the EUV exposed areas 312b and interfacial areas, which can be facilitated by a metal chelator to bind weaker bound metal species present in EUV unexposed areas, as compared to metal species (e.g., crosslinked metal or crosslinked metal-organic material) present in the EUV exposed area.

Developing steps can include use of aqueous or organic solvents in a liquid phase (e.g., as metal chelators). Additional development process conditions are described herein.

Optional steps may be conducted to further modulate, modify, or treat the EUV-sensitive film(s), substrate, photoresist layer(s), capping layer(s), and/or in any method herein. FIG. 3B provides a flow chart of an exemplary method 350 having various operations, including optional operations. As can be seen, in operation 352 a film is deposited employing the metal precursor.

In optional operation 354, the backside surface or bevel of the substrate can be cleaned, and/or an edge bead of the photoresist that was deposited in the prior step can be removed. Such cleaning or removing steps can be useful for removing particles that may be present after depositing a photoresist layer. The removing step can include processing the wafer with a wet metal oxide (MeOx) edge bead removal (EBR) step.

In another instance, the method can include optional operation 356 of performing a post application bake (PAB) of the deposited photoresist layer, thereby removing residual moisture from the layer to form a film; or pretreating the photoresist layer in any useful manner. The optional PAB can occur after film deposition and prior to EUV exposure; and the PAB can involve a combination of thermal treatment, chemical exposure, and moisture to increase the EUV sensitivity of the film, thereby reducing the EUV dose to develop a pattern in the film. In particular embodiments, the PA B step is conducted at a temperature greater than about 100° C. or at a temperature of from about 100° C. to about 200° C. or from about 100° C. to about 250° C. In some instances, a PA B is not performed within the method. In other instances, the PA B step is conducted at a temperature less than about 180° C., less than about 200° C., or less than about 250° C.

In operation 358, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist or a negative tone resist, as described herein.

Operation 360 is an optional post exposure bake (PEB) of the exposed film, thereby further removing residual moisture, promoting chemical condensation within the film, or increasing contrast in etch selectivity of the exposed film; or post-treating the film in any useful manner. Non-limiting examples of temperature for PEB include, for example from about 90° C. to 600° C., 100° C. to 400° C., 125° C. to 300° C., 170° C. to 250° C. or more, 190° C. to 240°, as well as others described herein. In other instances, the PEB step is conducted at a temperature less than about 180° C., less than about 200° C., or less than about 250° C.

In one instance, the exposed film can be thermally treated (e.g., optionally in the presence of various chemical species) to promote reactivity within the EUV exposed portions of the resist upon exposure to a stripping agent (e.g., a halide-based etchant, such as HCl, HBr, H₂, Cl₂, Br₂, BCl₃, or combinations thereof; an aqueous alkali development solution; or an organic development solution) or a positive tone developer. In another instance, the exposed film can be thermally treated to further cross-link ligands within the EUV exposed portions of the resist, thereby providing EUV unexposed portions that can be selectively removed upon exposure to a stripping agent (e.g., a negative tone developer).

Then, in operation 362 the PR pattern is developed in the presence of one or more metal chelator(s). In various embodiments of development, the exposed regions are removed (positive tone) or the unexposed regions are removed (negative tone). In various embodiments, these steps may be wet processes including such metal chelator(s).

In another instance, the method can include (e.g., after development) hardening the patterned film, thereby providing a resist mask disposed on a top surface of the substrate. Hardening steps can include any useful process to further crosslink or react the EUV unexposed or exposed areas, such as steps of exposing to plasma (e.g., O₂, Ar, He, or CO₂ plasma), exposing to ultraviolet radiation, annealing (e.g., at a temperature of about 180° C. to about 240° C.), thermal baking, or combinations thereof that can be useful for a post development baking (PD B) step. In other instances, the PDB step is conducted at a temperature less than about 180° C., less than about 200° C., or less than about 250° C. Additional post-application processes are described herein and may be conducted as an optional step for any method described herein.

Any useful type of chemistry can be employed during the depositing, patterning, stripping, and/or developing steps. Such steps may be based on dry processes employing chemistry in a gaseous phase or wet processes employing chemistry in a wet phase. In one example, spin-on EUV photoresists (wet process), such as available from Inpria Corp., may be combined with other wet or dry processes as described herein. In various embodiments, the wafer clean may be a wet process as described herein. In yet other embodiments, a wet development process may be used in combination with a spin-on EUV photoresist or with a dry deposited EUV photoresist.

### Metal Chelators

The metal chelator can include any ligand that can bind to metal centers (e.g., transition metal centers). Non-limiting ligands include those having hydroxyl, carboxyl, amido, amino, and/or oxo moieties. The metal chelator can be any useful compound having such ligands, in which compounds can include polymers, dicarbonyls (e.g., diketones), ketones, hydroxyketones (e.g., hydroxypyridinones, hydroxypyrimidones, or hydroxypyrones), alcohols (e.g., diols, triols, etc.), acids (e.g., carboxylic acids, diacids, triacids, hydroxycarboxylic acids, etc.), hydroxyacids (e.g., hydroxycarboxylic acids), amides, hydroxyamides, hydroxamic acids, lactones, hydroxylactones (e.g., ascorbic acid), as well as substituted versions thereof. Yet other non-limiting metal chelators (e.g., wet versions of dry metal chelators) can be any described in U.S. Provisional Pat. Appl. No. 63/199,129, filed Dec. 8, 2020, and titled PHOTORESIST DEVELOPMENT WITH ORGANIC VAPOR, which is incorporated herein by reference.

In other embodiments, the metal chelator is or includes a dicarbonyl. Non-limiting dicarbonyls include a 1,3-diketone, e.g., R^{A1}+C(O)—C(R^{1a}R^{2a})—C(O)R^{A2}, in which each of R^{A1} and R^{A2} is, independently, optionally substituted alkyl, optionally substituted haloalkyl, halo, optionally substituted alkoxy, hydroxyl, optionally substituted aryl, or a leaving group or optionally in which R^{A1} and R^{A2}, when taken together, forms a cyclic group (e.g., an optionally substituted cycloalkyl or an optionally substituted heterocyclyl); and in which each of R^{1a} and R^{2a} is, independently, H or an optional substituent provided for alkyl, as defined herein. Particular dicarbonyls include acetylacetone.

In some embodiments, the metal chelator is or includes an alcohol. A non-limiting alcohol is R^{A1}—OH, in which R^{A1} is optionally substituted alkyl, optionally substituted hydroxyalkyl, optionally substituted hydroxyaryl, optionally substituted carboxyalkyl, optionally substituted carboxyaryl, or optionally substituted aryl. Non-limiting alcohols include catechol and glycol.

In other embodiments, the metal chelator is or includes a carboxylic acid. A non-limiting carboxylic acid is R^{A1}—CO₂H, in which R^{A1} is H, optionally substituted alkyl, optionally substituted hydroxyalkyl, optionally substituted hydroxyaryl, optionally substituted carboxyalkyl, optionally substituted carboxyaryl, or optionally substituted aryl. Another non-limiting carboxylic acid is HO₂C—R^{Ak}—CO₂H, in which R^{Ak} is a bond, optionally substituted alkylene, or optionally substituted arylene (e.g., optionally substituted with halo, hydroxyl, carboxyl, alkoxy, and/or haloalkyl). In particular embodiments, the carboxylic acid is formic acid, citric acid, or salicylic acid.

In yet other embodiments, the metal chelator is or includes a hydroxamic acid, such as R^{A1}—C(O)NR^{A2}OH, in which each of R^{A1} and R^{A2} is, independently, H, optionally substituted alkyl, or optionally substituted aryl, or optionally in which R^{A1} and R^{A2}, when taken together, forms an optionally substituted heterocyclyl.

The metal chelator can be or include a hydroxyketone. In particular embodiments, the hydroxyketone is R^{A1}—C(O)—R^{A2}, in which each of R^{A1} and R^{A2} is an optionally substituted alkylene, optionally substituted alkenylene, an optionally substituted heteroalkylene, or an optionally substituted heteroalkenylene; at least one of R^{A1} and R^{A2} includes a hydroxyl substitution; and in which R^{A1} and R^{A2}, taken together, form a cyclic group (e.g., optionally substituted cycloalkyl or optionally substituted heterocyclyl).

In other embodiments, the hydroxyketone can have a structure of formula (I), (II), or (III):

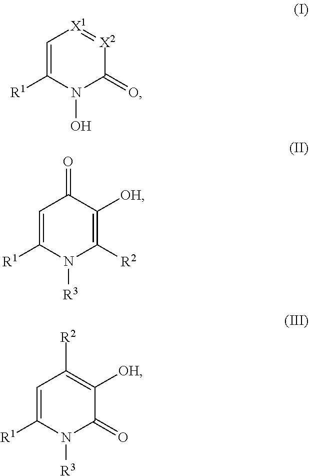

or a salt thereof, wherein:
each of X¹ and X² is, independently, —CR¹═ or —N═;
each R¹ and R² is, independently, H, optionally substituted alkyl, optionally substituted hydroxyalkyl, optionally substituted carboxyalkyl, —C(O)NR^{N1}R^{N2}, or —C(O)OR^{O1}, wherein each of R^{N1}, R^{N2}, and R^{O1} is, independently, H, or optionally substituted alkyl, in which optionally R^{N1} and R^{N2}, when taken together, forms an optionally substituted heterocyclyl; and
R³ is, independently, H, optionally substituted alkyl, or optionally substituted aryl.

Non-limiting hydroxyketones include a hydroxypyridinone, a hydroxypyrimidone, or a hydroxypyrone, including substituted forms thereof. Further hydroxyketones include 1-hydroxypyridin-2-one (1,2-HOPO, including 6-R¹ substituted 1,2-HOPO), 3-hydroxypyridin-4-one (3,4-HOPO, such as N-R³ substituted 3,4-HOPO, as well as N-R³, 2-R², 6-R³ substituted 3,4-HOPO), 3-hydroxypyridin-2-one (3,2-HOPO, such as N-R³ substituted 3,2-HOPO, as well as 4-R³, 6-R¹ substituted 3,2-HOPO), 1-hydroxypyrazin-2-one (1,2,4-HPM, including 6-R¹ substituted 1,2,4-HPM), 1-hydroxypyridimin-2-one (1,2,3-HPM, including 6-R¹ substituted 1,2,3-HPM), and 3-hydroxypyran-4-one (3,4-HPy, including 2-R¹ substituted 3,4-HPy, 5-R² substituted, and 2-R¹, 5-R² substituted 3,4-HPy), in which non-limiting substituents are described as in for formula (I), (II), or (III).

In some embodiments, the metal chelator includes a plurality of moieties disposed on a backbone, wherein the plurality of moieties is selected from hydroxyl, carboxyl, amido, amino, and oxo. Non-limiting moieties include one or more of a monovalent or multivalent form of a dicarbonyl, a diol, a carboxylic acid, a diacid, a triacid, a hydroxycarboxylic acid, a hydroxamic acid, a hydroxylactone, a hydroxyketone, or a salt thereof.

The backbone can include any useful structure, including an optionally substituted alkyl, optionally substituted heteroalkyl, optionally substituted aryl, as well as combinations thereof. In other embodiments, the backbone includes a polymer, such as a poly(ester), such as polyethylene terephthalate, polyhydroxybutyrate, polyhydroxyvalerate, poly(vinyl ester), poly(vinyl acetate), or copolymers thereof; a poly(hydroxyalkanoate); a poly(lactic acid); a poly(caprolactone); a polysaccharide or a derivative thereof, such as amylose, cellulose, or carboxymethyl cellulose; a poly(alkylene succinate), such as poly(propylene succinate) or poly(butylene succinate); a poly(aspartate) or a poly(aspartic acid); or an aliphatic-aromatic resin, such as a copolymer having at least one aliphatic section and at least one aromatic section.

### Metal Precursors

The present disclosure relates to use of metal precursor(s) and optional counter-reactant(s) that can be deposited to form a patterning radiation-sensitive film (e.g., an EUV-sensitive film). This film, in turn, can serve as an EUV resist, as further described herein. In particular embodiments, the film can include one or more ligands (e.g., labile ligands) that can be removed, cleaved, or cross-linked by radiation (e.g., EUV or DUV radiation).

The metal precursor can include any precursor (e.g., described herein) that provides a patternable film that is sensitive to radiation (or a patterning radiation-sensitive film or a photopatternable film). Such radiation can include EUV radiation, DUV radiation, or UV radiation that is provided by irradiating through a patterned mask, thereby being a patterning radiation. The film itself can be altered by being exposed to such radiation, such that the film is radiation-sensitive. In particular embodiments, the metal precursor is an organometallic compound, which includes at least one metal center.

The metal precursor can have any useful number and type of ligand(s). In some embodiments, the ligand can be characterized by its ability to react in the presence of a counter-reactant or in the presence of patterning radiation. For instance, the metal precursor can include a ligand (e.g., dialkylamino groups or alkoxy groups) that reacts with a counter-reactant, which can introduce linkages between metal centers (e.g., an —O-linkage). In another instance, the metal precursor can include a ligand that eliminates in the presence of patterning radiation. Such a ligand (e.g., EUV-cleavable labile ligand) can include branched or linear alkyl groups having a beta-hydrogen, as well as other described herein (e.g., R in formula (IV) or (V)).

The metal precursor can be any useful metal-containing precursor, such as an organometallic agent, a metal halide, or a capping agent (e.g., as described herein). In a non-limiting instance, the metal precursor includes a structure having formula (IV):

MₐR_{b} (IV),
wherein:
   M is a metal or an atom having a high EUV absorption cross-section;
   each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
   a≥1; and b≥1.

In another non-limiting instance, the metal precursor includes a structure having formula (V):

MₐR_{b}L_{c} (V),
wherein:
   M is a metal or an atom having a high EUV absorption cross-section;
   each R is, independently, halo, optionally substituted alkyl, optionally substituted aryl, optionally substituted amino, optionally substituted alkoxy, or L;
   each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
   a≥1; b≥1; and c≥1.

In some embodiments, each ligand within the metal precursor can be one that is reactive with a counter-reactant. In one instance, the metal precursor includes a structure having formula (V), in which each R is, independently, L. In another instance, the metal precursor includes a structure having formula (Va):

MₐL_{c} (Va),
wherein:
   M is a metal or an atom having a high EUV absorption cross-section;
   each L is, independently, a ligand, ion, or other moiety that is reactive with a counter-reactant, in which two L, taken together, can optionally form a heterocyclyl group;
   a≥1; and c≥1.

In particular embodiments of formula (Va), a is 1. In further embodiments, c is 2, 3, or 4.

For any formula herein, M can be a metal a metalloid or an atom with a high patterning radiation absorption cross-section (e.g., an EUV absorption cross-section that is equal to or greater than 1×10⁷ cm²/mol). In some embodiments, M is tin (Sn), tellurium (Te), bismuth (Bi), antimony (Sb), tantalum (Ta), cesium (Cs), indium (In), molybdenum (Mo), hafnium (Hf), iodine (I), zirconium (Zr), iron (Fe), cobalt (Co), nickel (Ni), copper (Cu), zinc (Zn), silver (Ag), and platinum (Pt). In further embodiments, M is Sn, a is 1, and c is 4 in formula (IV), (V), or (Va). In other embodiments, M is Sn, a is 1, and c is 2 in formula (IV), (V), or (Va). In particular embodiments, M is Sn(II) (e.g., in formula (IV), (V), or (Va)), thereby providing a metal precursor that is a Sn(II)-based compound. In other embodiments, M is Sn(IV) (e.g., in formula (IV), (V), or (Va)), thereby providing a metal precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl; or in which R¹ from a first R and R¹ from a second R, taken together with the oxygen atom and the metal atom to which each are attached, form a heterocyclyl group, as defined herein.

In some embodiments, at least one of R or L (e.g., in formula (IV), (V), or (Va)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, R or L has at least one beta-hydrogen or beta-fluorine.

In some embodiments, each R or L or at least one R or L (e.g., in formula (IV), (V), or (Va)) is halo. In particular, the metal precursor can be a metal halide. Non-limiting metal halides include SnBr₄, SnCl₄, SnI₄, and SbCl₃.

In some embodiments, each R or L or at least one R or L (e.g., in formula (IV), (V), or (Va)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, —NEt₂, —NHEt, —NMeEt, —N(t-Bu)-[CHCH₃]₂-N(t-Bu)-(tbba), —N(SiMe₃)₂, and —N(SiEt₃)₂.

In some embodiments, each R or L or at least one R or L (e.g., in formula (IV), (V), or (Va)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (IV), (V), or (Va)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine, an optionally substituted ether, an optionally substituted alkyl, an optionally substituted alkene, an optionally substituted alkyne, an optionally substituted benzene, oxo, or carbon monoxide.

Any formulas herein can include one or more multidentate (e.g., bidentate) ligands. Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the metal precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., -N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃CI), dimethyl tin dichloride (SnMe₂Cl₂), methyl tin trichloride (SnMeCl₃), tetraallyltin, tetravinyl tin, hexaphenyl ditin (IV) (Ph₃Sn-SnPh₃, in which Ph is phenyl), dibutyldiphenyltin (SnBu₂Ph₂), trimethyl (phenyl) tin (SnMe₃Ph), trimethyl (phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino]tin (Sn[N(SiMe₃)₂]₂).

In other embodiments, the metal precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the metal precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl) tellurium (Te(SiMe₃)₂), and bis(triethylsilyl) tellurium (Te(SiEt₃)₂).

The metal precursor can also include cesium. Non-limiting cesium precursors include Cs(OR), wherein R is optionally substituted C₁₋₁₂ alkyl or optionally substituted aryl. Other cesium precursors include Cs(Ot-Bu) and Cs(Oi-Pr).

The metal precursor can include antimony, such as in SbR₃, wherein each R is, independently, halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include SbCl₃, Sb(OEt)₃, Sb(On-Bu)₃, and Sb(NMe₂)₃.

Other metal precursors include indium precursors, such as in InR₃, wherein each R is, independently, halo, optionally substituted C₁₋₁₂ alkyl (e.g., methyl, ethyl, isopropyl, t-butyl, and neopentyl), or a diketonate (e.g., —OC(R⁴)-Ak-(R⁵)CO—, in which each R⁴ and R⁵ is, independently, H or C₁₋₁₂ alkyl). Non-limiting indium precursors include InCp, in which Cp is cyclopentadienyl, InCl₃, InMe₃, In(acac)₃, In(CF₃COCHCOCH₃)₃, and In(thd)₃.

Yet other metal precursors include molybdenum precursors, such as MoR₄, MoR₅, or MoR₆, wherein each R is, independently, optionally substituted C₁₋₁₂ alkyl (e.g., methyl, ethyl, isopropyl, t-butyl, and neopentyl), optionally substituted allyl (e.g., allyl, such as C₃H₅, or oxide of allyl, such as C₅H₅O), optionally substituted alkylimido (e.g., ═N-R¹), acetonitrile, optionally substituted amino (e.g., —NR¹R²), halo (e.g., chloro or bromo), carbonyl, a diketonate (e.g., —OC(R³)-Ak-(R³)CO—), or a bidentate chelating dinitrogen (e.g., —N(R³)-Ak-N(R³)— or —N(R⁴)—CR⁵—CR²═N(R³)—). In particular embodiments, each R¹ and each R² is, independently, H or optionally substituted alkyl; each R³ is, independently, H, optionally substituted alkyl, optionally substituted haloalkyl, or optionally substituted aryl; and R⁴ and R⁵, taken together, forms an optionally substituted heterocyclyl. Non-limiting molybdenum precursors include Mo(CO)₆, bis(t-butylimido) bis(dimethylamino) molybdenum (VI) or Mo(NMe₂)₂(═Nt-Bu)₂, molybdenum (VI) dioxide bis(2,2,6,6-tetramethyl-3,5-heptanedionate) or Mo(═O)₂(thd)₂, or molybdenum allyl complexes, such as Mo(η³-allyl)X(CO)₂(CH₃CN)₂, in which allyl can be C₃H₅ or C₅H₅O and X can be Cl, Br, or alkyl (e.g., methyl, ethyl, isopropyl, t-butyl, or neopentyl).

Metal precursors can also include hafnium precursors, such as HfR₃ or HfR₄, wherein each R is, independently, optionally substituted C₁₋₁₂ alkyl, optionally substituted C₁₋₁₂ alkoxy, mono-C₁₋₁₂ alkylamino (e.g., —NR¹H, in which R¹ is optionally substituted C₁₋₁₂ alkyl), di-C₁₋₁₂ alkylamino (e.g., —NR¹R², in which each R¹ and R² is, independently, optionally substituted C₁₋₁₂ alkyl), optionally substituted aryl (e.g., phenyl, benzene, or cyclopentadienyl, as well as substituted forms thereof), optionally substituted allyl (e.g., allyl or allyl oxide), or diketonate (e.g., —OC(R⁴)-Ak-(R⁵)CO—, each R⁴ and R⁵ is, independently, H or optionally substituted C₁₋₁₂ alkyl). Non-limiting hafnium precursors include Hf(i-Pr)(NMe₂)₃; Hf(η-C₆H₅R¹)(η-C₃H₅)₂ in which R¹ is H or alkyl; HfR¹(NR²R³)₃ in which each of R¹, R², and R³ is, independently, optionally substituted C₁₋₁₂ alkyl (e.g., methyl, ethyl, isopropyl, t-butyl, or neopentyl); HfCp₂Me₂; Hf(Ot-Bu)₄; Hf(OEt)₄; Hf(NEt₂)₄; Hf(NMe₂)₄; Hf(NMeEt)₄; and Hf (thd)₄.

Yet other metal precursors and non-limiting substituents are described herein. For instance, metal precursors can be any having a structure of formulas (IV), (V), and (Va), as described above; or formulas (VI), (VII), (VIII), (IX), (X), or (XI), as described below. Any of the substituents M, R, X, or L, as described herein, can be employed in any of formulas (IV), (V), (Va), (VI), (VII), (VIII), (IX), (X), or (XI).

Various atoms present in the metal precursor and/or counter-reactant can be provided within a gradient film. In some embodiments of the techniques discussed herein, a non-limiting strategy that can further improve the EUV sensitivity in a photoresist (PR) film is to create a film in which the film composition is vertically graded, resulting in depth-dependent EUV sensitivity. In a homogenous PR with a high absorption coefficient, the decreasing light intensity throughout the film depth necessitates a higher EUV dose to ensure the bottom is sufficiently exposed. By increasing the density of atoms with high EUV absorptivity at the bottom of the film relative to the top of the film (i.e., by creating a gradient with increasing EUV absorption), it becomes possible to more efficiently use available EUV photons while more uniformly distributing absorption (and the effects of secondary electrons) towards the bottom of more highly absorbing films. In one non-limiting instance, the gradient film includes Te, I, or other atoms towards the bottom of the film (e.g., closer to the substrate).

The strategy of engineering a vertical composition gradient in a PR film is particularly applicable to dry deposition methods, such as MLD, CVD, and ALD, and can be realized by tuning the flow ratios between different reactants during deposition. The type of composition gradients that can be engineered include: the ratios between different high-absorbing metals, the percentage of metal atoms that have EUV-cleavable organic groups, the percentages of counter-reactants that contain high-absorbing elements, and combinations of the above.

The composition gradient in the EUV PR film can also bring additional benefits. For instance, high density of high-EUV-absorbing elements in the bottom part of the film can effectively generate more secondary electrons that can better expose upper portions of the film. In addition, such compositional gradients can also be directly correlated with a higher fraction of EUV absorbing species that are not bonded to bulky, terminal substituents. For example, in the case of Sn-based resists, the incorporation of tin precursors with four leaving groups is possible, thereby promoting the formation of Sn—O-substrate bonding at the interface for improved adhesion.

Such gradient films can be formed by using any metal precursors (e.g., tin or non-tin precursors) and/or counter-reactants described herein. Yet other films, methods, precursors, and other compounds are described in U.S. Provisional Pat. Appl. No. 62/909,430, filed Oct. 2, 2019, and International Appl No. PCT/US20/53856, filed Oct. 1, 2020, published as International Pub. No. WO 2021/067632, in which each is titled SUBSTRATE SURFACE MODIFICATION WITH HIGH EUV ABSORBERS FOR HIGH PERFORMANCE EUV PHOTORESISTS; and International Appl. No. PCT/US20/70172, filed Jun. 24, 2020, published as International Pub. No. WO 2020/264557, and titled PHOTORESIST WITH MULTIPLE PATTERNING RADIATION-ABSORBING ELEMENTS AND/OR VERTICAL COMPOSITION GRADIENT, the disclosures of which at least relating to the composition, deposition, and patterning of directly photopatternable metal oxide films to form EUV resist masks are incorporated by reference herein.

Furthermore, two or more different precursors can be employed within each layer (e.g., a film). For instance, two or more of any metal-containing precursors herein can be employed to form an alloy. In one non-limiting instance, tin telluride can be formed by employing tin precursor including an —NR² ligand with RTeH, RTeD, or TeR₂ precursors, in which R is an alkyl, particularly t-butyl or i-propyl. In another instance, a metal telluride can be formed by using a first metal precursor including an alkoxy or a halo ligand (e.g., SbCl₃) with a tellurium-containing precursor including a trialkylsilyl ligand (e.g., bis(trimethylsilyl) tellurium).

Yet other exemplary EUV-sensitive materials, as well as processing methods and apparatuses, are described in U.S. Pat. No. 9,996,004 and Int. Pat. Pub. No. WO 2019/217749, each of which is incorporated herein by reference in its entirety.

As described herein, the films, layers, and methods herein can be employed with any useful precursor. In some instances, the metal precursor includes a metal halide having the following formula (VI):

MXₙ (VI),
in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting metal-containing precursor includes a structure having formula (VII):

MRₙ (VII),
in which M is a metal; each R is independently H, an optionally substituted alkyl, amino (e.g., —NR₂, in which each R is independently alkyl), optionally substituted bis(trialkylsilyl)amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRn, RTeR, t-butyl tellurium hydride (Te(t-Bu)(H)), dimethyl tellurium (TeMe₂), di(t-butyl) tellurium (Te(t-Bu)₂), di(isopropyl) tellurium (Te(i-Pr)₂), bis(trimethylsilyl) tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting metal-containing precursor can include a capping agent having the following formula (VIII):

MLₙ (VIII),
in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy, and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn (t-BuO)₄. In some embodiments, multiple types of ligands are present.

A metal-containing precursor can include a hydrocarbyl-substituted capping agent having the following formula (IX):

RₙMXₘ (IX),
wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4-n, 3-n, or 2-n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino) tin (Sn(t-Bu)(NMe₂)₃), n-butyltris(dimethylamino) tin (Sn(n-Bu)(NMe₂)₃), t-butyltris (diethylamino) tin (Sn (t-Bu) (NEt₂)₃), di(t-butyl) di(dimethylamino) tin (Sn (t-Bu) (NMe₂)₂), sec-butyltris(dimethylamino) tin(Sn(s-Bu)(NMe₂)₃), n-pentyltris(dimethylamino) tin (Sn(n-pentyl) (NMe₂)₃), i-butyltris(dimethylamino) tin (Sn(i-Bu) (NMe₂)₃), i-propyltris (dimethylamino) tin (Sn(i-Pr)(NMe₂)₃), t-butyltris(t-butoxy)tin (Sn (t-Bu) (t-BuO)₃), n butyl (tris(t-butoxy)tin (Sn(n-Bu) (t-BuO)₃), or isopropyltris(t-butoxy)tin (Sn(i-Pr) (t-BuO)₃).

In various embodiments, a metal-containing precursor includes at least one alkyl group on each metal atom that can survive the vapor-phase reaction, while other ligands or ions coordinated to the metal atom can be replaced by the counter-reactants. Accordingly, another non-limiting metal-containing precursor includes an organometallic agent having the formula (X):

MₐR_{b}L_{c} (X),
in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting metal-containing precursor includes an organometallic agent having the formula (XI):

MₐL_{c} (XI),
in which M is a metal; L is a ligand, ion, or other moiety which is reactive with the counter-reactant; a>1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 2n+1<x≤1. In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Exemplary organometallic agents include SnMeCl₃, (N²,N³-di-t-butyl-butane-2,3-diamido)tin (II) (Sn (tbba)), bis(bis(trimethylsilyl) amido)tin (II), tetrakis(dimethylamino) tin (IV) (Sn(NMe₂)₄), t-butyl tris(dimethylamino) tin (Sn (t-butyl) (NMe₂)₃), i-butyl tris(dimethylamino) tin (Sn(i-Bu) (NMe₂)₃), n-butyl tris(dimethylamino) tin (Sn(n-Bu) (NMe₂)₃), sec-butyl tris(dimethylamino) tin(Sn(s-Bu)(NMe₂)₃), i-propyl (tris) dimethylamino tin (Sn(i-Pr)(NMe₂)₃), n-propyl tris(diethylamino) tin (Sn(n-Pr) (NEt₂)₃), and analogous alkyl (tris) (t-butoxy)tin compounds, such as t-butyl tris(t-butoxy)tin (Sn (t-Bu) (t-BuO)₃). In some embodiments, the organometallic agents are partially fluorinated.

### Lithographic Processes

EUV lithography makes use of EUV resists, which may be polymer-based chemically amplified resists produced by liquid-based spin-on techniques, metal oxide-based resists produced by spin-on techniques, or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a metal-containing precursor (e.g., any described herein) to form a metal oxide (e.g., a layer including a network of metal oxide bonds, which may include other non-metal and non-oxygen groups) film as the imaging/PRlayer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon absorption and generate secondary electrons and/or show increased etch selectivity to an underlying film stack and device layers. Of note, wet (solvent) approaches are encompassed by this disclosure. For wet development, the wafer can be exposed to developing solvent, dried, and baked.

### Deposition Processes, Including Dry or Wet Deposition

As discussed above, the present disclosure provides methods for making imaging layers on semiconductor substrates, which may be patterned using EUV or other next generation lithographic techniques. Methods include those where polymerized organometallic materials are produced in a vapor or in a solvent and then deposited on a substrate. In some embodiments, deposition can employ any useful metal-containing precursor (e.g., metal halides, capping agents, or organometallic agents described herein) as a dry formulation or as a spin-on formulation. Deposition processes can include applying a EUV-sensitive material as a resist film. Exemplary EUV-sensitive materials are described herein.

The present technology includes methods by which EUV-sensitive films are deposited on a substrate, such films being operable as resists for subsequent EUV lithography and processing.

Such EUV-sensitive films comprise materials which, upon exposure to EUV, undergo changes, such as the loss of bulky pendant ligands bonded to metal atoms in low density M-OH rich materials, allowing their crosslinking to denser M-O-M bonded metal oxide materials. In other embodiments, EUV exposure results in further cross-linking between ligands bonded to metal atoms, thereby providing denser M-L-M bonded organometallic materials, in which L is a ligand. In yet other embodiments, EUV exposure results in loss of ligands to provide M-OH materials that can be removed by positive tone developers.

Through EUV patterning, areas of the film are created that have altered physical or chemical properties relative to unexposed areas. These properties may be exploited in subsequent processing, such as to dissolve either unexposed or exposed areas or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density, and cross-linking of the film. Removal may be by wet processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10 nm to 20 nm. Moreover, as discussed above, the deposited films may closely conform to surface features, providing advantages in forming masks over substrates, such as substrates having underlying features, without “filling in” or otherwise planarizing such features.

The film (e.g., imaging layer) may be composed of a metal oxide layer deposited in any useful manner. Such a metal oxide layer can be deposited or applied by using any EUV-sensitive material described herein, such as a metal-containing precursor (e.g., a metal halide, a capping agent, or an organometallic agent). In exemplary processes, a polymerized organometallic material is formed in vapor phase, in a liquid phase, or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the underlayer.

Exemplary deposition techniques (e.g., for a film) include any described herein, such as ALD (e.g., thermal ALD and plasma-enhanced ALD), spin-coat deposition, PVD including PVD co-sputtering, CV D (e.g., PE-CVD or LP-CVD), sputter deposition, e-beam deposition including e-beam co-evaporation, etc., or a combination thereof, such as ALD with a CVD component, such as a discontinuous, ALD-like process in which metal-containing precursors and counter-reactants are separated in either time or space.

Further description of precursors and methods for their deposition as EUV photoresist films applicable to this disclosure may be found in International Appl. No. PCT/US19/31618, published as International Pub. No. WO 2019/217749, filed May 9, 2019, and titled METHODS FOR MAKING EUV PATTERNABLE HARD MASKS. The thin films may include optional materials in addition to a metal precursor and a counter-reactant to modify the chemical or physical properties of the film, such as to modify the sensitivity of the film to EUV or enhancing etch resistance. Such optional materials may be introduced, such as by doping prior to deposition on the substrate, after deposition of the film, or both. In some embodiments, a gentle remote H₂ plasma may be introduced so as to replace some Sn-L bonds with Sn-H, for example, which can increase reactivity of the resist under EUV.

Dry deposition methods can include mixing a vapor stream of a metal precursor (e.g., a metal-containing precursor, such as an organometallic agent) with an optional vapor stream of a counter-reactant so as to form a polymerized organometallic material, and depositing the organometallic material onto the surface of the semiconductor substrate. In some embodiments, mixing the metal-containing precursor with the optional counter-reactant can form a polymerized organometallic material. As will be understood by one of ordinary skill, the mixing and depositing aspects of the process may be concurrent, in a substantially continuous process. Wet deposition methods can include providing such precursors or polymerized organometallic material within a liquid solvent.

In an exemplary continuous CVD process, two or more gas streams, in separate inlet paths, of sources of metal precursor and optional counter-reactant are introduced to the deposition chamber of a CV D apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of metal precursor and optional counter-reactant are mixed in the chamber, allowing the metal precursor and optional counter-reactant to react to form a polymerized organometallic material or a film (e.g., a metal oxide coating or agglomerated polymeric materials, such as via metal-oxygen-metal bond formation).

For depositing metal oxide, the CV D process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CV D process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate.

Deposition methods may be used to tune the composition of the film as it grows. In a CVD process, this may be accomplished by changing the relative flows of the metal precursor and the counter-reactant during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the metal precursor and optional counter-reactant are introduced at separate times, representing an ALD cycle. The metal precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different metal precursors. In one embodiment, the precursors can include the same metal but different ligands. In another embodiment, the precursors can include different metal groups. In one non-limiting instance, alternating flows of various volatile metal-containing precursors can provide a mixed metal layer, such as use of a metal alkoxide precursor having a first metal (e.g., Sn) with a silyl-based precursor having a different second metal (e.g., Te). Also, any of the deposition methods herein can be modified to allow for use of two or more different counter-reactants.

Furthermore, any of the deposition methods herein can be modified to provide one or more layers within a film. In one instance, different metal precursors can be employed in each layer. In another instance, the same precursor may be employed for each layer, but the top-most layer can possess a different chemical composition (e.g., a different density of metal-ligand bonds, a different metal to carbon ratio, or a different bound ligand, as provided by modulating or changing the metal precursor).

Processes herein can be used to achieve a surface modification. In some iterations, a vapor of the metal precursor may be passed over the wafer. The wafer may be heated to provide thermal energy for the reaction to proceed. In some iterations, the heating can be between about 50° C. to about 250° C. In some cases, pulses of the counter-reactant may be used, separated by pump and/or purging steps. For instance, a counter-reactant may be pulsed between the precursor pulses resulting in ALD or ALD-like growth. In other cases, both the precursor and the counter-reactant may be flowed at the same time. Examples of elements useful for surface modification include I, F, Sn, Bi, Sb, Te, and oxides or alloys of these compounds.

The processes herein can be used to deposit a thin metal oxide or metal. Examples include SnOx, BiOx, and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then be ready for the EUV-sensitive film to be deposited. One possible method is to produce a thin film of SnOx.

Possible chemistries include growth of SnO₂ by cycling tetrakis(dimethylamino) tin and a counter-reactant such as water or O₂ plasma. After the growth, a capping agent could be used. For example, isopropyltris(dimethylamino) tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a capping layer can be deposited), or on an underlayer.

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Various advantages may derive from the conformance of the films of the present technology to underlying features without “filling in” or otherwise planarizing such features, and the ability to deposit films on a wide variety of material surfaces.

In some embodiments, an incoming wafer can be prepared with a substrate surface of a desired material, with the uppermost material being the layer into which the resist pattern is transferred. While the material selection may vary depending on integration, it is generally desired to select a material that can be etched with high selectivity to (i.e., much faster than) the EUV resist or imaging layer. Suitable substrate materials can include various carbon-based films (e.g., ashable hard mask (AHM)), silicon-based films (e.g., silicon, silicon oxide, silicon nitride, silicon oxynitride, or silicon oxycarbonitride, as well as doped forms thereof, including SiOₓ, SiOₓN_{y}, SiOₓC_{y}N_{z}, a-Si: H, poly-Si, or SiN), or any other (generally sacrificial) film applied to facilitate the patterning process.

In some embodiments, the substrate is a hard mask, which is used in lithographic etching of an underlying semiconductor material. The hard mask may comprise any of a variety of materials, including amorphous carbon (a-C), SnOₓ, SiO₂, SiOₓN_{y}, SiOₓC, Si₃N₄, TiO₂, TiN, W, W-doped C, WOₓ, HfO₂, ZrO₂, and Al₂O₃. For example, the substrate may preferably comprise SnOx, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In some embodiments, a surface activation operation may be used to activate the surface (e.g., of the substrate and/or a film) for future operations. For example, for a SiOₓ surface, a water or oxygen/hydrogen plasma may be used to create hydroxyl groups on the surface. For a carbon- or hydrocarbon-based surface, various treatment (e.g., a water, hydrogen/oxygen, CO₂ plasma, or ozone treatment) may be used to create carboxylic acids/or hydroxyl groups. Such approaches can prove critical for improving the adhesion of resist features to the substrate, which might otherwise delaminate or lift off during handling or within the solvent during development.

Adhesion may also be enhanced by inducing roughness in the surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed, in which a chemically reactive oxygen-containing plasma such as CO₂, O₂, or H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges. In other embodiments, EUV exposure provides cross-linked organic moieties by photopolymerizing ligands within the film; or EUV exposures releases gaseous by-products resulting from photolysis of bonds within a ligand.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure is typically performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include known methods and equipment.

In some EUV lithography techniques, an organic hardmask (e.g., an ashable hardmask of PECVD amorphous hydrogenated carbon) is patterned. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hardmask process and related vacuum-integrated hardware that combines film formation (deposition/condensation) and optical lithography with the result of greatly improved EUV lithography (EUV L) performance—e.g., reduced line edge roughness-is disclosed herein.

In various embodiments described herein, a deposition (e.g., condensation) process (e.g., ALD or MOCVD carried out in a PECVD tool, such as the Lam Vector®; or a spin-on process) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, typically under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber. In yet other embodiments, the photosensitive metal film deposition and EUV exposure may be conducted in different chambers.

### Development Processes, Including Wet Development

EUV exposed or unexposed areas can be removed by any useful development process. In one embodiment, the EUV exposed area can have activated reactive centers, such as dangling metal bonds, M-H groups, or dimerized M-M bonds. In particular embodiments, M-H groups can be selectively removed by employing one or more development processes. In other embodiments, M-M bonds can be selectively removed by employing a wet development process, e.g., use of hot ethanol and water to provide soluble M(OH)ₙ groups. In yet other embodiments, EUV exposed areas are removed by use of wet development (e.g., by using a positive tone developer). In some embodiments, EUV unexposed areas are removed by use of wet development (e.g., by using a negative tone developer).

In some embodiments, dry and wet operations can be combined to provide a dry/wet process. For any of the process herein (e.g., for lithographic processes, deposition processes, EUV exposure processes, development processes, pre-treatment processes, post-application processes, etc.), various specific operation can include wet, dry, or wet and dry embodiments. For instance, wet deposition can be combined with wet development; or dry deposition can be combined with wet development. Any of these, in turn, can be combined with wet or dry pre- and post-application processes, as described herein.

In particular embodiments, wet development methods can also be employed. In particular embodiments, such wet developments methods are used to remove EUV exposed regions to provide a positive tone photoresist or a negative tone resist. Exemplary, non-limiting wet development can include use of an alkaline developer (e.g., an aqueous alkaline developer), such as those including ammonium, e.g., ammonium hydroxide (NH₄OH); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., diethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, Or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds, some of which are described herein.

Other development methodologies can include use of an acidic developer (e.g., an aqueous acidic developer or an acid developer in an organic solvent) that includes a halide (e.g., HCl or HBr), an organic acid (e.g., formic acid, acetic acid, or citric acid), or an organofluorine compound (e.g., trifluoroacetic acid); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof.

In particular embodiments, the positive tone developer is an aqueous alkaline developer (e.g., including NH₄OH, TMAH, TEAH, TPAH, or TBAH). In other embodiments, the negative tone developer is an aqueous acidic developer, an acidic developer in an organic solvent, or an organic developer (e.g., HCl, HBr, formic acid, trifluoroacetic acid, 2-heptanone, IPA, PGME, PGM EA, or combinations thereof).

### Post-Application Processes

The methods herein can include any useful post-application processes, as described below.

For the backside and bevel clean process, the vapor and/or the plasma can be limited to a specific region of the wafer to ensure that only the backside and the bevel are removed, without any film degradation on the frontside of the wafer. The deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BCl₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 M Hz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

Photolithography processes typically involve one or more bake steps, to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post treatments to metal and/or metal oxide-based photoresists after deposition (e.g., post-application bake (PA B)) and/or exposure (e.g., post-exposure bake (PEB)) and/or development (e.g., post-development bake (PDB)) are capable of increasing material property differences between exposed and unexposed photoresist and therefore decreasing dose to size (DtS), improving PR profile, and improving line edge and width roughness (LER/LWR) after subsequent development.

In the case of post-application processing (e.g., PA B), a thermal process with control of temperature, gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the development rate difference between the unexposed and exposed photoresist. A higher development selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂.

In the case of post-development processing (e.g., post development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase development selectivity. For instance, thermal or radical modification can increase the contrast between unexposed and exposed material and thus increase the selectivity of the subsequent development step.

Without wishing to be limited by mechanism, wet development can rely on material solubility, in which heating to or beyond 220° C., for example, can greatly increase the degree of cross-linking in both exposed and unexposed regions of a metal-containing PR film such that both become insoluble in the wet development solvents, so that the film can no longer by reliably wet developed. For instance, for wet spin-on or wet-developed metal-containing PR films, baking such as PA B, PEB may be performed, for example at temperatures below 180° C. or below 200° C. or below 250° C. The treatment temperature in a PA B, PEB, or PDB can be varied across a window to tune and optimize the treatment process, for example from about 90° C. to 250° C., such as 90° C. to 190° C., 90° C. to 600° C., 100° C. to 400° C., 125° C. to 300° C., and about 170° C. to 250° C. or more, such as 190° C. to 240° C. (e.g., for PAB, PEB, and/or PDB). Decreasing etch rate and greater etch selectivity has been found to occur with higher treatment temperatures in the noted ranges.

In particular embodiments, the PA B, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 1 to 15 minutes, for example about 2 minutes.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained than would be possible in a wet development context.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing an EUV-sensitive material as a film by providing a metal precursor in the optional presence of a counter-reactant; a patterning module comprising an EUV photolithography tool with a source of sub-30 nm wavelength radiation; and a development module comprising a chamber for developing the film in the presence of a metal chelator.

The apparatus can further include a controller having instructions for such modules. In one embodiment, the controller includes one or more memory devices, one or more processors, and system control software coded with instructions for conducting deposition of the film. Such instructions can include instructions for, in the deposition module, depositing a metal precursor as a film on a top surface of a substrate or a photoresist layer; in the patterning module, patterning the film with sub-30 nm resolution directly by EUV exposure, thereby forming a pattern within the film; and in the development module, developing the film in the presence of a metal chelator. In particular embodiments, the development module provides for removal of the EUV exposed or EUV unexposed areas, thereby providing a pattern within the film.

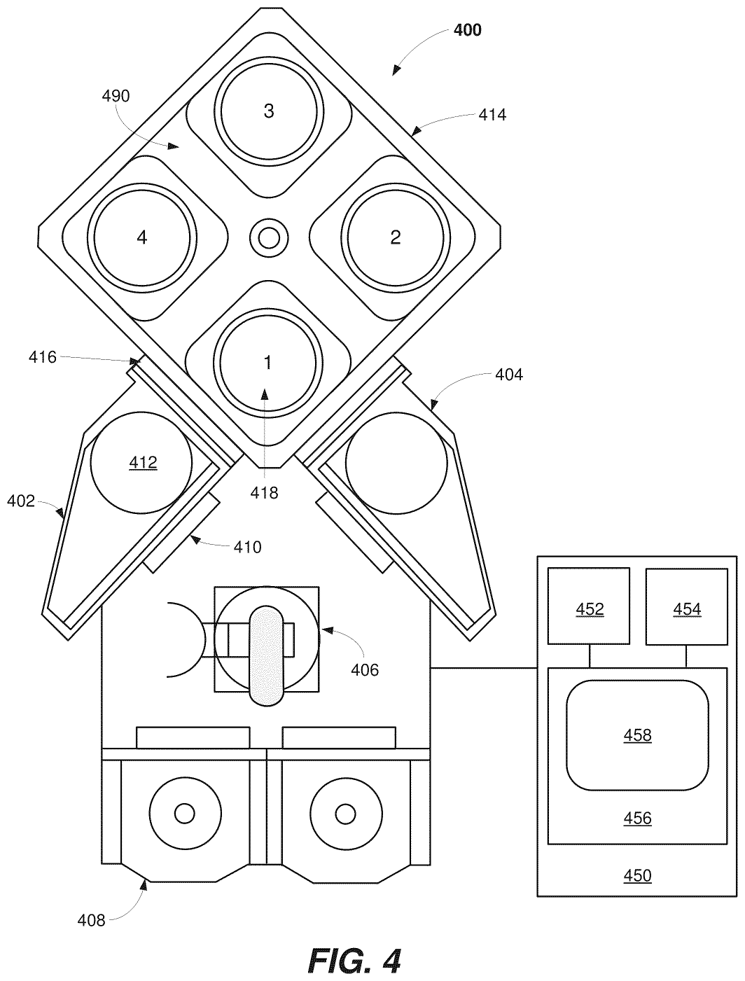

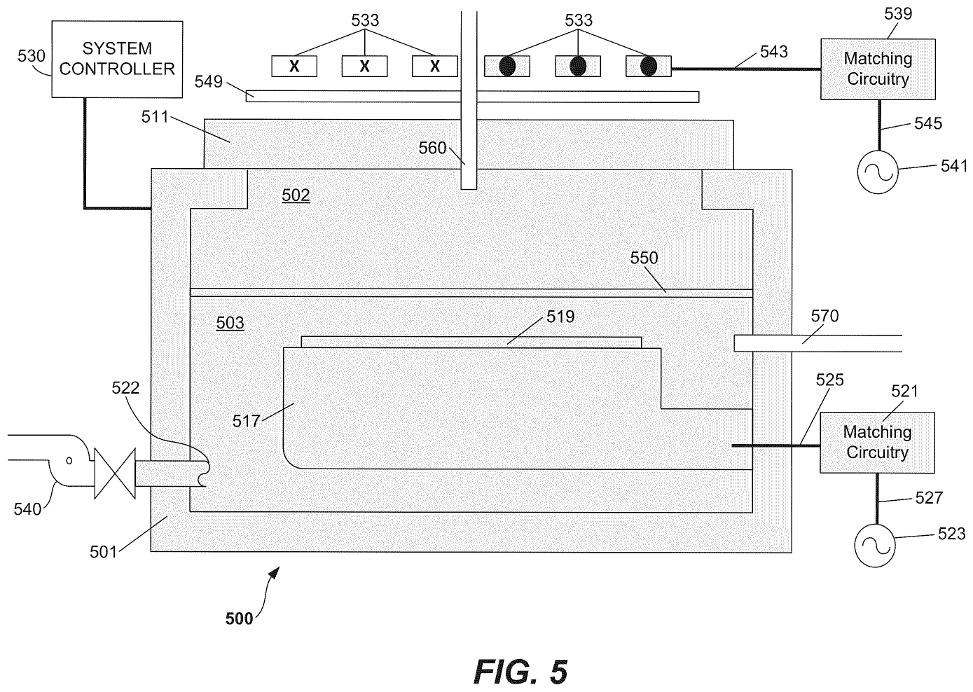

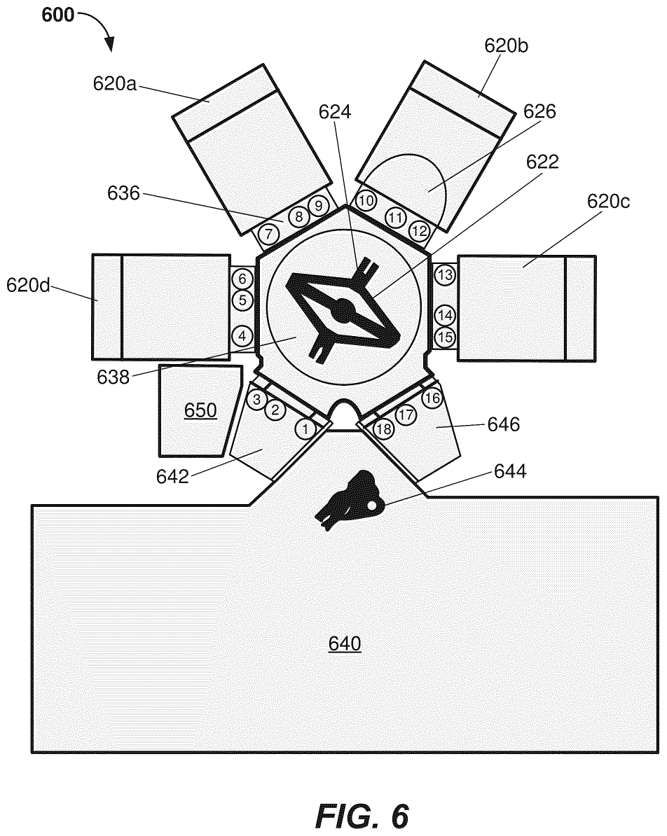

FIG. 4 depicts an embodiment of a multi-station processing tool 400, such as a VECTOR® processing tool available from Lam Research Corporation, Fremont, CA. A process station may be configured as a module in a cluster tool. FIG. 6 depicts a semiconductor process cluster tool architecture with vacuum-integrated deposition and patterning modules suitable for implementation of the embodiments described herein. Such a cluster process tool architecture can include resist deposition, resist exposure (EUV scanner), resist development and etch modules, as described herein with reference to FIG. 5 and FIG. 6.

In some embodiments, certain of the processing functions can be performed consecutively in the same module. And embodiments of this disclosure are directed to methods and apparatus for receiving a wafer, including a photopatterned EUV resist thin film layer disposed on a layer or layer stack to be etched, to a development/etch chamber (e.g., a wet development/etch chamber) following photopatterning in an EUV scanner; developing a photopatterned EUV resist thin film layer; and then etching the underlying layer using the patterned EUV resist as a mask, as described herein.

The wet development chamber can be any configured to provide a developer to the exposed film or substrate. In one instance, the chamber can contain a wet developer therein, and the exposed film or substrate is immersed within the wet developer (e.g., such as in immersion development). In another instance, the chamber can include one or more showerheads, sprays, nozzles, dispensers, and the like, to deliver the wet developer to the exposed film or substrate (e.g., such as in spray-on development).

The substrate, in turn, can be provided within the chamber and disposed upon a pedestal. For instance, the substrate can be located beneath a dispenser and resting upon a pedestal. In some embodiments, the pedestal may be raised or lowered to expose the substrate to a volume between the substrate and the showerhead. Furthermore, the pedestal may be rotated during delivery of the wet developer. Thus, in some embodiments, the pedestal may include a rotational axis for rotating the substrate. It will be appreciated that, in some embodiments, one or more of these example adjustments may be performed programmatically by one or more suitable computer controllers.

As described above, one or more process stations may be included in a multi station processing tool. FIG. 4 shows a schematic view of an embodiment of a multi station processing tool 400 with an inbound load lock 402 and an outbound load lock 404, either or both of which may include a remote plasma source. A robot 406 at atmospheric pressure is configured to move wafers from a cassette loaded through a pod 408 into inbound load lock 402 via an atmospheric port 410 A wafer is placed by the robot 406 on a pedestal 412 in the inbound load lock 402, the atmospheric port 410 is closed, and the load lock is pumped down. Where the inbound load lock 402 includes a remote plasma source, the wafer may be exposed to a remote plasma treatment to treat the silicon nitride surface in the load lock prior to being introduced into a processing chamber 414. Further, the wafer also may be heated in the inbound load lock 402 as well, for example, to remove moisture and adsorbed gases. Next, a chamber transport port 416 to processing chamber 414 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 414 includes four process stations, numbered from 1 to 4 in the embodiment shown in FIG. 4. Each station has a heated pedestal (shown at 418 for station 1), and gas line inlets. It will be appreciated that in some embodiments, each process station may have different or multiple purposes. While the depicted processing chamber 414 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 4 depicts an embodiment of a wafer handling system 490 for transferring wafers within processing chamber 414. In some embodiments, wafer handling system 490 may transfer wafers between various process stations and/or between a process station and a load lock. It will be appreciated that any suitable wafer handling system may be employed. Non limiting examples include wafer carousels and wafer handling robots. FIG. 4 also depicts an embodiment of a system controller 450 employed to control process conditions and hardware states of process tool 400. System controller 450 may include one or more memory devices 456, one or more mass storage devices 454, and one or more processors 452 Processor 452 may include a CPU or computer, analog, and/or digital input/output connections, stepper motor controller boards, etc.

In some embodiments, system controller 450 controls all of the activities of process tool 400. System controller 450 executes system control software 458 stored in mass storage device 454, loaded into memory device 456, and executed on processor 452. Alternatively, the control logic may be hard coded in the controller 450. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 458 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 400. System control software 458 may be configured in any suitable way. For example, various process tool component subroutines or control objects may be written to control operation of the process tool components used to carry out various process tool processes. System control software 458 may be coded in any suitable computer readable programming language.

In some embodiments, system control software 458 may include input/output control (IOC) sequencing instructions for controlling the various parameters described above. Other computer software and/or programs stored on mass storage device 454 and/or memory device 456 associated with system controller 450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 418 and to control the spacing between the substrate and other parts of process tool 400.

A process gas control program may include code for controlling various gas compositions (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 450. The user interface may include a display screen, graphical software displays of the apparatus and/or process conditions, and user input devices such as pointing devices, keyboards, touch screens, microphones, etc.

In some embodiments, parameters adjusted by system controller 450 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 450 from various process tool sensors. The signals for controlling the process may be output on the analog and digital output connections of process tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 450 may provide program instructions for implementing the above-described deposition processes. The program instructions may control a variety of process parameters, such as DC power level, RF bias power level, pressure, temperature, etc. The instructions may control the parameters to operate development and/or etch processes according to various embodiments described herein.

The system controller 450 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 450.

In some implementations, the system controller 450 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 450, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 450 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 450 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 450, in some implementations, may be a part of or coupled to a computer that is integrated with, coupled to the system, otherwise networked to the system, or a combination thereof. For example, the system controller 450 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 450 receives instructions in the form of data, which specify parameters for each of the processing steps to be performed during one or more operations. It should be understood that the parameters may be specific to the type of process to be performed and the type of tool that the system controller 450 is configured to interface with or control. Thus, as described above, the system controller 450 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a wet development chamber or module, and any other semiconductor processing systems that may be associated or used in the fabrication and/or manufacturing of semiconductor wafers.

As noted above, depending on the process step or steps to be performed by the tool, the system controller 450 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 5 schematically shows a cross-sectional view of an inductively coupled plasma apparatus 500 appropriate for implementing certain embodiments or aspects of embodiments such as etch, an example of which is a Kiyo® reactor, produced by Lam Research Corp. of Fremont, CA. In other embodiments, other tools or tool types having the functionality to conduct the etch processes described herein may be used for implementation.

The inductively coupled plasma apparatus 500 includes an overall process chamber structurally defined by chamber walls 501 and a window 511. The chamber walls 501 may be fabricated from stainless steel or aluminum. The window 511 may be fabricated from quartz or other dielectric material. An optional internal plasma grid 550 divides the overall process chamber into an upper sub-chamber 502 and a lower sub-chamber 503. In most embodiments, plasma grid 550 may be removed, thereby utilizing a chamber space made of sub-chambers 502 and 503. A chuck 517 is positioned within the lower sub-chamber 503 near the bottom inner surface. The chuck 517 is configured to receive and hold a semiconductor wafer 519 upon which the etching and deposition processes are performed. The chuck 517 can be an electrostatic chuck for supporting the wafer 519 when present. In some embodiments, an edge ring (not shown) surrounds the chuck 517 and has an upper surface that is approximately planar with a top surface of the wafer 519, when present over the chuck 517. The chuck 517 also includes electrostatic electrodes for chucking and dechucking the wafer 519. A filter and DC clamp power supply (not shown) may be provided for this purpose.

Other control systems for lifting the wafer 519 off the chuck 517 can also be provided. The chuck 517 can be electrically charged using an RF power supply 523. The RF power supply 523 is connected to matching circuitry 521 through a connection 527. The matching circuitry 521 is connected to the chuck 517 through a connection 525. In this manner, the RF power supply 523 is connected to the chuck 517. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 533 positioned above window 511. In some embodiments, a coil is not used in disclosed embodiments. The coil 533 is fabricated from an electrically conductive material and includes at least one complete turn. The example of a coil 533 shown in FIG. 5 includes three turns. The cross sections of coil 533 are shown with symbols, and coils having an “X” extend rotationally into the page, while coils having a “.” extend rotationally out of the page. Elements for plasma generation also include an RF power supply 541 configured to supply RF power to the coil 533. In general, the RF power supply 541 is connected to matching circuitry 539 through a connection 545. The matching circuitry 539 is connected to the coil 533 through a connection 543. In this manner, the RF power supply 541 is connected to the coil 533. An optional Faraday shield 549 is positioned between the coil 533 and the window 511. The Faraday shield 549 may be maintained in a spaced apart relationship relative to the coil 533. In some embodiments, the Faraday shield 549 is disposed immediately above the window 511. In some embodiments, a Faraday shield is between the window 511 and the chuck 517. In some embodiments, the Faraday shield is not maintained in a spaced apart relationship relative to the coil 533. For example, a Faraday shield may be directly below the window without a gap. The coil 533, the Faraday shield 549, and the window 511 are each configured to be substantially parallel to one another. The Faraday shield 549 may prevent metal or other species from depositing on the window 511 of the process chamber.

Process gases may be flowed into the process chamber through one or more main gas flow inlets 560 positioned in the upper sub-chamber 502 and/or through one or more side gas flow inlets 570. Likewise, though not explicitly shown, similar gas flow inlets may be used to supply process gases to a capacitively coupled plasma processing chamber. A vacuum pump, e.g., a one or two stage mechanical dry pump and/or turbomolecular pump 540, may be used to draw process gases out of the process chamber and to maintain a pressure within the process chamber. For example, the vacuum pump may be used to evacuate the lower sub-chamber 503 during a purge operation of ALD. A valve-controlled conduit may be used to fluidically connect the vacuum pump to the process chamber so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 500, one or more process gases may be supplied through the gas flow inlets 560 and/or 570. In certain embodiments, process gas may be supplied only through the main gas flow inlet 560, or only through the side gas flow inlet 570. In some cases, the gas flow inlets shown in the figure may be replaced by more complex gas flow inlets, one or more showerheads, for example. The Faraday shield 549 and/or optional grid 550 may include internal channels and holes that allow delivery of process gases to the process chamber. Either or both of Faraday shield 549 and optional grid 550 may serve as a showerhead for delivery of process gases. In some embodiments, a liquid vaporization and delivery system may be situated upstream of the process chamber, such that once a liquid reactant or precursor is vaporized, the vaporized reactant or precursor is introduced into the process chamber via a gas flow inlet 560 and/or 570.

Radio frequency power is supplied from the RF power supply 541 to the coil 533 to cause an RF current to flow through the coil 533. The RF current flowing through the coil 533 generates an electromagnetic field about the coil 533. The electromagnetic field generates an inductive current within the upper sub-chamber 502. The physical and chemical interactions of various generated ions and radicals with the wafer 519 etch features of and selectively deposit layers on the wafer 519.

If the plasma grid 550 is used such that there is both an upper sub-chamber 502 and a lower sub-chamber 503, the inductive current acts on the gas present in the upper sub-chamber 502 to generate an electron-ion plasma in the upper sub-chamber 502. The optional internal plasma grid 550 limits the amount of hot electrons in the lower sub-chamber 503. In some embodiments, the apparatus 500 is designed and operated such that the plasma present in the lower sub-chamber 503 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 503 through port 522. The chuck 517 disclosed herein may operate at elevated temperatures ranging between about 10° C. and about 250° C. The temperature will depend on the process operation and specific recipe.

Apparatus 500 may be coupled to facilities (not shown) when installed in a clean room or a fabrication facility. Facilities include plumbing that provide processing gases, vacuum, temperature control, and environmental particle control. These facilities are coupled to apparatus 500, when installed in the target fabrication facility. Additionally, apparatus 500 may be coupled to a transfer chamber that allows robotics to transfer semiconductor wafers into and out of apparatus 500 using typical automation.

In some embodiments, a system controller 530 (which may include one or more physical or logical controllers) controls some or all of the operations of a process chamber. The system controller 530 may include one or more memory devices and one or more processors. In some embodiments, the apparatus 500 includes a switching system for controlling flow rates and durations when disclosed embodiments are performed. In some embodiments, the apparatus 500 may have a switching time of up to about 600 ms, or up to about 750 ms. Switching time may depend on the flow chemistry, recipe chosen, reactor architecture, and other factors.

In some implementations, the system controller 530 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 530, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 530 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 530, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 530 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 530 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a wet development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL. The EUVL patterning tool may be a standalone device from which the substrate is moved into and out of for deposition and etching as described herein. Or, as described below, the EUVL patterning tool may be a module on a larger multi-component tool. FIG. 6 depicts a semiconductor process cluster tool architecture with vacuum-integrated deposition, EUV patterning and development/etch modules that interface with a vacuum transfer module, suitable for implementation of the processes described herein. While the processes may be conducted without such vacuum integrated apparatus, such apparatus may be advantageous in some implementations.

FIG. 6 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 638 interfaces with four processing modules 620a-620d, which may be individually optimized to perform various fabrication processes. By way of example, processing modules 620a-620d may be implemented to perform deposition, evaporation, ELD, development, etch, strip, and/or other semiconductor processes. For example, module 620a may be an ALD reactor that may be operated to perform in a non-plasma, thermal atomic layer depositions as described herein, such as a Vector tool, available from Lam Research Corporation, Fremont, CA. And module 620b may be a PECVD tool, such as the Lam Vector®. It should be understood that the figure is not necessarily drawn to scale.

Airlocks 642 and 646, also known as a loadlocks or transfer modules, interface with the VTM 638 and a patterning module 640. For example, as noted above, a suitable patterning module may be the TWINSCAN NXE: 3300B® platform supplied by ASML of Veldhoven, NL. This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 6 but without the integrated patterning module.

Airlock 642 may be an “outgoing” loadlock, referring to the transfer of a substrate out from the VTM 638 serving a deposition module 620a to the patterning module 640, and airlock 646 may be an “ingoing” loadlock, referring to the transfer of a substrate from the patterning module 640 back in to the VTM 638. The ingoing loadlock 646 may also provide an interface to the exterior of the tool for access and egress of substrates. Each process module has a facet that interfaces the module to VTM 638. For example, deposition process module 620a has facet 636. Inside each facet, sensors, for example, sensors 1-18 as shown, are used to detect the passing of wafer 626 when moved between respective stations. Patterning module 640 and airlocks 642 and 646 may be similarly equipped with additional facets and sensors, not shown.

Main VTM robot 622 transfers wafer 626 between modules, including airlocks 642 and 646. In one embodiment, robot 622 has one arm, and in another embodiment, robot 622 has two arms, where each arm has an end effector 624 to pick wafers such as wafer 626 for transport. Front-end robot 644, in is used to transfer wafers 626 from outgoing airlock 642 into the patterning module 640, from the patterning module 640 into ingoing airlock 646. Front-end robot 644 may also transport wafers 626 between the ingoing loadlock and the exterior of the tool for access and egress of substrates. Because ingoing airlock module 646 has the ability to match the environment between atmospheric and vacuum, the wafer 626 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 642 may provide this function by holding the transferred wafers at a lower pressure, no higher than the pressure in the patterning module 640, for a period of time and exhausting any off-gassing, so that the optics of the patterning tool 640 are not contaminated by off-gassing from the substrate. A suitable pressure for the outgoing, off-gassing airlock is no more than 1E-8 Torr.

In some embodiments, a system controller 650 (which may include one or more physical or logical controllers) controls some or all of the operations of the cluster tool and/or its separate modules. It should be noted that the controller can be local to the cluster architecture, or can be located externally to the cluster architecture in the manufacturing floor, or in a remote location and connected to the cluster architecture via a network. The system controller 650 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for optimizing a development contrast between exposed and unexposed areas of an organometallic-based photoresist, the method comprising:
contacting the organometallic-based photoresist with a chemical compound in a process chamber, wherein the chemical compound comprises one or more ligands, each ligand having a hydroxyl, carboxyl, amido, amino, and/or oxo moieties, wherein the chemical compound comprises a ketone, an alcohol, a diol, a carboxylic acid, or a combination thereof, wherein the chemical compound increases a development contrast between exposed and unexposed areas of the organometallic-based photoresist.

2. The method of claim 1, wherein the chemical compound comprises a ketone.

3. The method of claim 1, wherein the chemical compound comprises an alcohol.

4. The method of claim 1, wherein the chemical compound comprises a diol.

5. The method of claim 1, wherein the chemical compound comprises a carboxylic acid.

6. The method of claim 5, wherein the chemical compound comprises formic acid.

7. The method of claim 1, wherein contacting the organometallic-based photoresist with the chemical compound takes place in the presence of a developer, wherein the developer comprises a halide-based etchant.

8. The method of claim 7, wherein the halide-based etchant comprises a hydrogen halide.

9. The method of claim 8, wherein the hydrogen halide comprises HCl.

10. The method of claim 8, wherein the hydrogen halide comprises HBr.

11. The method of claim 7, wherein the halide-based etchant comprises BCl₃.

12. The method of claim 1, wherein the contacting the organometallic-based photoresist with the chemical compound takes place in the presence of water.

13. The method of claim 12, wherein the chemical compound comprises a carboxylic acid.

14. The method of claim 1, wherein the chemical compound comprises a carboxylic acid, wherein contacting the organometallic-based photoresist with the chemical compound takes place in the presence of water and hydrogen halide.

15. The method of claim 1, wherein contacting the organometallic-based photoresist with the chemical compound takes place in the presence of hydrogen halide and water.

16. The method of claim 1, wherein the chemical compound comprises a metal chelator configured to bind to radiation exposed metal centers of an interfacial area, wherein the interfacial area is disposed between the exposed areas and the unexposed areas of the organometallic-based photoresist.

17. The method of claim 1, wherein the chemical compound facilitates release of volatile compounds present in the organometallic-based photoresist.

18. The method of claim 1, wherein the exposed areas comprise metal-oxygen (M-O) bonds, wherein the chemical compound is configured to remove weakly bound metal species in the metal-oxygen bonds in the exposed areas.

19. The method of claim 1, further comprising:
developing the organometallic-based photoresist by removing the unexposed areas of the organometallic-based photoresist.

20. A method of optimizing a development contrast between exposed and unexposed areas of an organometallic-based photoresist, the method comprising:
contacting the organometallic-based photoresist with a first chemical compound in a process chamber, wherein the first chemical compound comprises one or more ligands, each ligand having a hydroxyl, carboxyl, amido, amino, and/or oxo moieties, wherein the first chemical compound comprises a ketone, an alcohol, a diol, a carboxylic acid, or a combination thereof, wherein the first chemical compound increases a development contrast between exposed and unexposed areas of the organometallic-based photoresist; and
contacting the organometallic-based photoresist with a second chemical compound in the process chamber that is different from the first chemical compound, wherein the second chemical compound comprises a ketone, an alcohol, a diol, a carboxylic acid, or a combination thereof.

21. The method of claim 20, wherein the first chemical compound comprises a ketone.

22. The method of claim 20, wherein the first chemical compound comprises an alcohol.

23. The method of claim 20, wherein the first chemical compound comprises a diol.

24. The method of claim 20, wherein the first chemical compound comprises a carboxylic acid.

25. The method of claim 24, wherein the chemical compound comprises formic acid.

26. The method of claim 20, wherein contacting the organometallic-based photoresist with the first chemical compound takes place in the presence of a developer, wherein the developer comprises a halide-based etchant.

27. The method of claim 25, wherein the halide-based etchant comprises a hydrogen halide.

28. The method of claim 25, wherein the halide-based etchant comprises BCl₃.

29. The method of claim 20, wherein the contacting the organometallic-based photoresist with the first chemical compound takes place in the presence of water.

30. The method of claim 20, wherein the first chemical compound comprises a metal chelator configured to bind to radiation exposed metal centers of an interfacial area, wherein the interfacial area is disposed between the exposed areas and the unexposed areas of the organometallic-based photoresist.

31. A method for developing an organometallic-based photoresist, the method comprising:
contacting the organometallic-based photoresist with a chemical compound and a developer in a process chamber to develop the organometallic-based photoresist, wherein the developer comprises a halide-based etchant, wherein the chemical compound increases a development contrast between exposed and unexposed areas of the organometallic-based photoresist, wherein the chemical compound facilitates release of volatile compounds present in the organometallic-based photoresist, and wherein the volatile compounds comprise volatile tin-containing compounds, wherein the chemical compound comprises one or more ligands, each ligand having a hydroxyl, carboxyl, amido, amino, and/or oxo moieties.

32. The method of claim 31, wherein the chemical compound comprises a ketone.

33. The method of claim 31, wherein the chemical compound comprises an alcohol.

34. The method of claim 31, wherein the chemical compound comprises a diol.

35. The method of claim 31, wherein the chemical compound comprises a carboxylic acid.

36. The method of claim 35, wherein the chemical compound comprises formic acid.

37. The method of claim 31, wherein the contacting the organometallic-based photoresist with the chemical compound and the developer takes place in the presence of water.

38. The method of claim 31, wherein the chemical compound comprises a metal chelator configured to bind to radiation exposed metal centers of an interfacial area, wherein the interfacial area is disposed between the exposed areas and the unexposed areas of the organometallic-based photoresist.

39. The method of claim 31, wherein the halide-based etchant comprises a hydrogen halide.

40. The method of claim 31, wherein the halide-based etchant comprises BCl₃.
